(19) United States
(12) Patent Application Publication
(10) Pub. No.: US 2025/0040273 A1
(43) Pub. Date: Jan. 30, 2025

(54) PHOTOELECTRIC CONVERSION ELEMENT, METHOD OF MANUFACTURING PHOTOELECTRIC CONVERSION ELEMENT, PHOTOELECTRIC CONVERSION DEVICE, PHOTODETECTION SYSTEM, AND MOVABLE OBJECT

(71) Applicant: CANON KABUSHIKI KAISHA, Tokyo (JP)

(72) Inventor: MAHITO SHINOHARA, Tokyo (JP)

(21) Appl. No.: 18/913,823

(22) Filed: Oct. 11, 2024

Related U.S. Application Data
(63) Continuation of application No. PCT/JP2023/013796, filed on Apr. 3, 2023.

(30) Foreign Application Priority Data
Apr. 15, 2022 (JP) 2022-067524

(51) Int. Cl. H01L 27/146

(52) U.S. Cl. CPC H01L 27/1461; H01L 27/14683

(57) ABSTRACT

A photoelectric conversion element includes a first semiconductor region of a first conductivity type provided in contact with a first face of a semiconductor layer, a second semiconductor region of a second conductivity type provided closer to a second face of the semiconductor layer than the first semiconductor region, and a third semiconductor region provided closer to the second face than the second semiconductor region. The first semiconductor region and the second semiconductor region constitute an avalanche photodiode, and the avalanche photodiode is configured to multiply a signal charge generated in the third semiconductor region. A width in a depth direction of a region having an effective impurity density of 1×10¹⁶ cm⁻³ or more of the second semiconductor region is 0.5 μm or less.

### CROSS-REFERENCE TO RELATED APPLICATIONS

This application is a continuation of International Patent Application No. PCT/JP2023/013796, which was filed on Apr. 3, 2023 and which claims priority to Japanese Patent Application No. 2022-067524, which was filed on Apr. 15, 2022, both of which are hereby incorporated by reference herein in their entireties.

### BACKGROUND OF THE INVENTION

### Field of the Invention

The present invention relates to a photoelectric conversion element, a method of manufacturing a photoelectric conversion element, a photoelectric conversion device, a photodetection system, and a movable object.

### Description of the Related Art

Single photon avalanche diode (SPAD) is known as a detector capable of detecting weak light at a single photon level. The SPAD uses an avalanche multiplication phenomenon generated by a strong electric field induced in a p-n junction of a semiconductor to multiply a signal carrier excited by a photon to about several hundred times to several million times of carriers. By converting the current generated by the avalanche multiplication phenomenon into a pulse signal and counting the number of pulse signals, it is possible to directly measure the number of incident photons. Japanese Patent Application Laid-Open No. 2020-057650 describes a photodetection device and a photodetection system using SPADs.

The SPAD is an element that has a very high current gain and operates at a high voltage and requires very large energy per signal charge. Therefore, a sensor configured by using SPAD pixels requires very large electric power as compared with a CMOS sensor or the like, and deterioration of element characteristics due to heat generation is also large. In addition, in the SPAD pixel described in Japanese Patent Application Laid-Open No. 2020-057650, when the pixel is reduced in size, a lateral electric field between an n-type semiconductor region having a high impurity density constituting a cathode and a p-type semiconductor region having a high impurity density to which an anode electrode is connected becomes, high and a dark current due to a semiconductor surface may increase.

### SUMMARY OF THE INVENTION

An object of the present invention is to realize a photoelectric conversion element and a photoelectric conversion device capable of realizing a reduction in drive voltage.

According to one disclosure of the present specification, there is provided a photoelectric conversion element, provided in a semiconductor layer having a first face and a second face opposed to the first face, including a first semiconductor region of a first conductivity type provided in contact with the first face, a second semiconductor region of a second conductivity type provided closer to the second face than the first semiconductor region, a third semiconductor region provided closer to the second face than the second semiconductor region, a first impurity doped region to which an impurity of the first conductivity type is doped, a first electrode electrically connected to the first semiconductor region, and a second electrode electrically connected to the second semiconductor region, wherein the first semiconductor region and the second semiconductor region constitute an avalanche photodiode, and the avalanche photodiode is configured to multiply a signal charge generated in the third semiconductor region, wherein a width in a depth direction of a region having an effective impurity density of 1×10¹⁶ cm⁻³ or more of the second semiconductor region is 0.5 μm or less, wherein the first impurity doped region overlaps the second semiconductor region in a plan view and in the depth direction, wherein a depth at which a density of a first conductivity type impurity constituting the first impurity doped region has a peak is deeper than a depth at which a density of a second conductivity type impurity constituting the second semiconductor region has a peak, wherein an impurity density per unit area of the second conductivity type impurity constituting the second semiconductor region is 3×10¹² cm⁻² or more, and wherein an impurity density per unit area of the first conductivity type impurity constituting the first impurity doped region is not less than 5×10¹¹ cm⁻² and not more than ½ of an impurity density per unit area of the second conductivity type impurity constituting the second semiconductor region.

Further features of the present invention will become apparent from the following description of exemplary embodiments with reference to the attached drawings.

### BRIEF DESCRIPTION OF THE DRAWINGS

FIG. 1 and FIG. 2 are block diagrams illustrating a schematic configuration of a photoelectric conversion device according to a first embodiment of the present invention.

FIG. 3 is a block diagram illustrating a configuration example of a pixel of the photoelectric conversion device according to the first embodiment of the present invention.

FIG. 4 is a perspective view illustrating a configuration example of the photoelectric conversion device according to the first embodiment of the present invention.

FIG. 5A, FIG. 5B, and FIG. 5C are diagrams illustrating the basic operation of the photoelectric conversion unit of the photoelectric conversion device according to the first embodiment of the present invention.

FIG. 6 is a plan view illustrating a structure of the photoelectric conversion element of the photoelectric conversion device according to the first embodiment of the present invention.

FIG. 7 is a schematic cross-sectional view illustrating a structure of the photoelectric conversion element of the photoelectric conversion device according to the first embodiment of the present invention.

FIG. 8 is a diagram illustrating a depth distribution of impurity densities in the photoelectric conversion element of the photoelectric conversion device according to the first embodiment of the present invention.

FIG. 9 is a diagram illustrating a potential distribution in the photoelectric conversion element of the photoelectric conversion device according to the first embodiment of the present invention.

FIG. 10 is a plan view illustrating a structure of a photoelectric conversion element of a photoelectric conversion device according to a second embodiment of the present invention.

FIG. 11 is a schematic cross-sectional view illustrating a structure of the photoelectric conversion element of the photoelectric conversion device according to the second embodiment of the present invention.

FIG. 12 is a schematic cross-sectional view illustrating a structure of a photoelectric conversion element of a photoelectric conversion device according to a third embodiment of the present invention.

FIG. 13 is a block diagram illustrating a schematic configuration of a photodetection system according to a fourth embodiment of the present invention.

FIG. 14 is a block diagram illustrating a schematic configuration of a range image sensor according to a fifth embodiment of the present invention.

FIG. 15 is a schematic diagram illustrating a configuration example of an endoscopic surgical system according to a sixth embodiment of the present invention.

FIG. 16A, FIG. 16B and FIG. 16C are schematic diagrams illustrating an example of a configuration of a movable object according to a seventh embodiment of the present invention.

FIG. 17 is a block diagram illustrating a schematic configuration of a photodetection system according to the seventh embodiment of the present invention.

FIG. 18 is a flowchart illustrating an operation of the photodetection system according to the seventh embodiment of the present invention.

FIG. 19A and FIG. 19B are schematic diagrams illustrating a schematic configuration of a photodetection system according to an eighth embodiment of the present invention.

### DESCRIPTION OF THE EMBODIMENTS

The following embodiments are intended to embody the technical idea of the present invention, and do not limit the present invention. The sizes and positional relationships of members illustrated in the drawings may be exaggerated for clarity of description. In the following description, the same components are denoted by the same reference numerals, and the description thereof may be omitted.

### First Embodiment

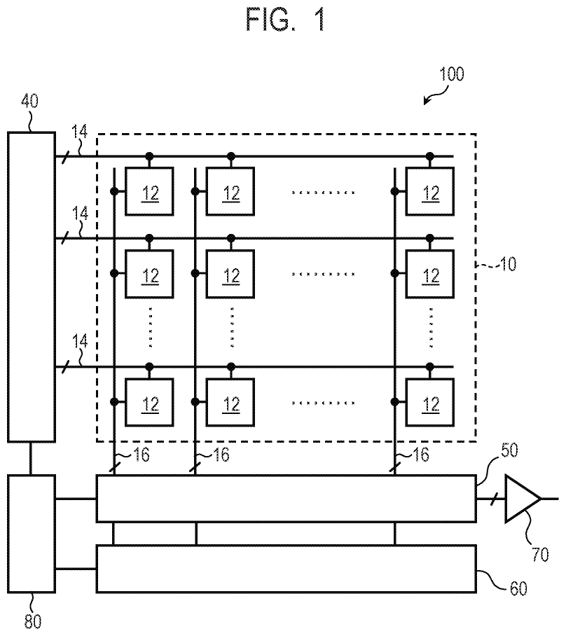

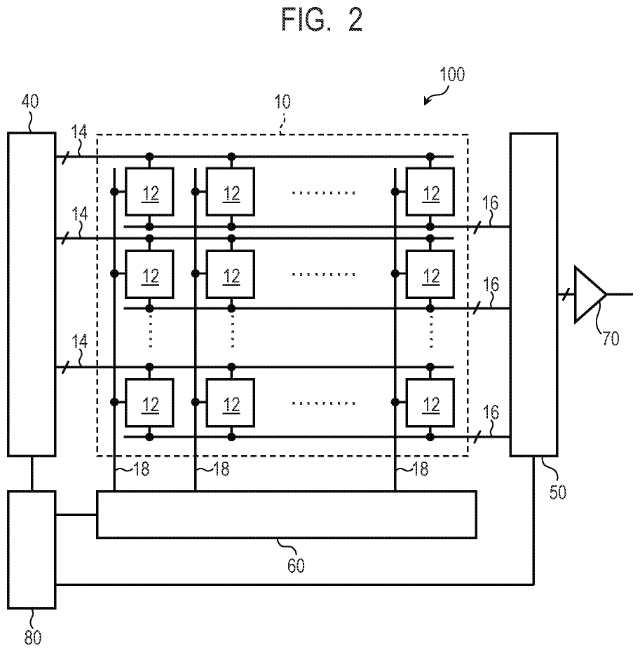

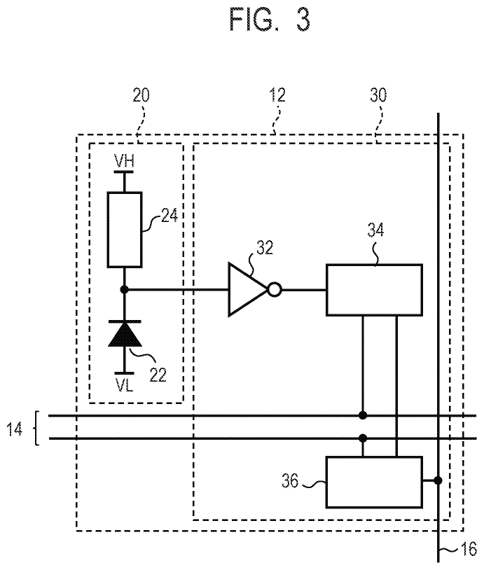

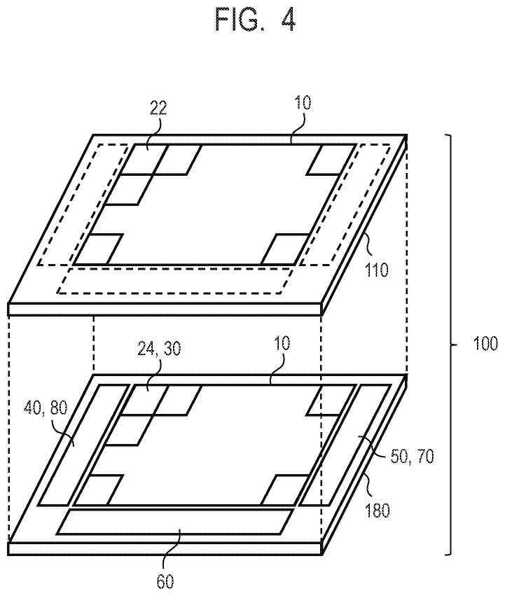

A schematic configuration of a photoelectric conversion device according to a first embodiment of the present invention will be described with reference to FIG. 1 to FIG. 4. FIG. 1 and FIG. 2 are block diagrams illustrating a schematic configuration of the photoelectric conversion device according to the present embodiment. FIG. 3 is a block diagram illustrating a configuration example of a pixel of the photoelectric conversion device according to the present embodiment. FIG. 4 is a perspective view illustrating a configuration example of the photoelectric conversion device according to the present embodiment.

As illustrated in FIG. 1, the photoelectric conversion device 100 according to the present embodiment includes a pixel region 10, a vertical scanning circuit unit 40, a readout circuit unit 50, a horizontal scanning circuit unit 60, an output circuit unit 70, and a control pulse generation unit 80.

The pixel region 10 is provided with a plurality of pixels 12 arranged in an array so as to form a plurality of rows and a plurality of columns. As described later, each pixel 12 may include a photoelectric conversion unit including a photoelectric conversion element and a pixel signal processing unit that processes a signal output from the photoelectric conversion unit. The number of pixels 12 constituting the pixel region 10 is not particularly limited. For example, like a general digital camera, the pixel region 10 may be constituted by a plurality of pixels 12 arranged in an array of several thousand rows×several thousand columns. Alternatively, the pixel region 10 may include a plurality of pixels 12 arranged in one row or one column. Alternatively, one pixel 12 may constitute the pixel region 10.

In each row of the pixel array of the pixel region 10, a control line 14 is arranged so as to extend in a first direction (lateral direction in FIG. 1). Each of the control lines 14 is connected to the pixels 12 arranged in the first direction on the corresponding row, respectively, and forms a signal line common to these pixels 12. The first direction in which the control lines 14 extend may be referred to as a row direction or a horizontal direction. Each of the control lines 14 may include a plurality of signal lines for supplying a plurality of types of control signals to the pixels 12. The control line 14 of each row is connected to the vertical scanning circuit unit 40.

Further, in each column of the pixel array of the pixel region 10, a data line 16 is arranged so as to extend in a second direction (vertical direction in FIG. 1) intersecting the first direction. Each of the data lines 16 is connected to the pixels 12 arranged in the second direction on the corresponding column, respectively, and forms a signal line common to these pixels 12. The second direction in which the data lines 16 extend may be referred to as a column direction or a vertical direction. Each of the data lines 16 may include a plurality of signal lines for transferring, e.g., a digital signal of a plurality of bits output from the pixel 12 on a bit-by-bit basis.

The control line 14 of each row is connected to the vertical scanning circuit unit 40. The vertical scanning circuit unit 40 is a control unit having a function of generating a control signal for driving the pixels 12 in response to a control signal output from the control pulse generation unit 80 and supplying the generated control signal to the pixels 12 via the control line 14. A logic circuit such as a shift register, or an address decoder may be used as the vertical scanning circuit unit 40. The vertical scanning circuit unit 40 sequentially scans the pixels 12 in the pixel region 10 in units of rows and makes the pixels 12 in the respective rows sequentially output the pixel signals to the readout circuit unit 50 via the data lines 16.

The data line 16 of each column is connected to the readout circuit unit 50. The readout circuit unit 50 includes a plurality of holding units (not illustrated) provided corresponding to the respective columns of the pixel array of the pixel region 10 and has a function of holding the pixel signals of the pixels 12 of the respective columns output in units of rows from the pixel region 10 via the data lines 16 in the holding units of the corresponding columns.

The horizontal scanning circuit unit 60 is a control unit having a function of generating a control signal for reading out a pixel signal from the holding unit of each column of the readout circuit unit 50 in response to a control signal output from the control pulse generation unit 80 and supplies the generated control signal to the readout circuit unit 50. A logic circuit such as a shift register, or an address decoder may be used as the horizontal scanning circuit unit 60. The horizontal scanning circuit unit 60 sequentially scans the holding units of each column of the readout circuit unit 50 and makes the holding units sequentially output the pixel signals held therein to the output circuit unit 70.

The output circuit unit 70 includes an external interface circuit and is a circuit unit for outputting the pixel signal output from the readout circuit unit 50 to the outside of the photoelectric conversion device 100. The external interface circuit included in the output circuit unit 70 is not particularly limited. As the external interface circuit, for example, a SerDes (SERializer/DESerializer) transmission circuit such as a LVDS (Low Voltage Differential Signaling) circuit or a SLVS (Scalable Low Voltage Signaling) circuit may be applied.

The control pulse generation unit 80 is a control circuit for generating control signals for controlling the operations and timings of the vertical scanning circuit unit 40, the readout circuit unit 50, and the horizontal scanning circuit unit 60, and supplying the generated control signal to each functional block. At least a part of the control signals for controlling the operations and timings of the vertical scanning circuit unit 40, the readout circuit unit 50, and the horizontal scanning circuit unit 60 may be supplied from the outside of the photoelectric conversion device 100.

The connection mode of each functional block of the photoelectric conversion device 100 is not limited to the configuration example of FIG. 1, and may be configured as illustrated in FIG. 2, for example.

In the configuration example of FIG. 2, a data line 16 extending in the first direction is arranged in each row of the pixel array of the pixel region 10. Each of the data lines 16 is connected to the pixels 12 arranged in the first direction on the corresponding row, respectively, and forms a signal line common to these pixels 12. A control line 18 extending in the second direction is arranged in each column of the pixel array of the pixel region 10. Each of the control lines 18 is connected to the pixels 12 arranged in the second direction on the corresponding column, respectively, and forms a signal line common to these pixels 12.

The control line 18 of each column is connected to the horizontal scanning circuit unit 60. The horizontal scanning circuit unit 60 generates a control signal for reading out a pixel signal from the pixel 12 in response to a control signal output from the control pulse generation unit 80 and supplies the generated control signal to the pixels 12 via the control line 18. Specifically, the horizontal scanning circuit unit 60 sequentially scans the plurality of pixels 12 in the pixel region 10 in units of columns and makes the pixels 12 in each row in the respective columns sequentially output the pixel signals to the data lines 16.

The data line 16 in each row is connected to the readout circuit unit 50. The readout circuit unit 50 includes a plurality of holding units (not illustrated) provided corresponding to each row of the pixel array of the pixel region 10 and has a function of holding the pixel signals of the pixels 12 of each row output from the pixel region 10 in units of columns via the data lines 16 in the holding units of the corresponding rows.

The readout circuit unit 50 sequentially outputs the pixel signals held in the holding units of the respective rows to the output circuit unit 70 in response to the control signal output from the control pulse generation unit 80.

Other constituent elements in the configuration example of FIG. 2 may be the same as those in the configuration example of FIG. 1.

Each of the pixels 12 may be configured by, as illustrated in, e.g., FIG. 3, a photoelectric conversion unit 20 and a pixel signal processing unit 30. The photoelectric conversion unit 20 may be configured by, for example, a photoelectric conversion element 22 and a quenching element 24. The pixel signal processing unit 30 may be configured by, for example, a waveform shaping unit 32, a counter circuit 34, and a selection circuit 36.

The photoelectric conversion element 22 may be an avalanche photodiode (hereinafter referred to as “APD”). An anode of the APD constituting the photoelectric conversion element 22 is connected to a node to which a voltage VL is supplied. A cathode of the APD constituting the photoelectric conversion element 22 is connected to one terminal of the quenching element 24. A connection node between the photoelectric conversion element 22 and the quenching element 24 is an output node of the photoelectric conversion unit 20. The other terminal of the quenching element 24 is connected to a node to which a voltage VH higher than the voltage VL is supplied. The voltage VL and the voltage VH are set so that a reverse bias voltage sufficient for the APD to perform the avalanche multiplication operation is applied. In one example, a negative high voltage is applied as the voltage VL, and a positive voltage comparable to the power supply voltage is applied as the voltage VH. In one example, the voltage VL may be −30 V, and the voltage VH may be 3 V, but from the viewpoint of improvement in element characteristics, suppression of deterioration, and the like, it is desired to lower the drive voltage of the APD.

The photoelectric conversion element 22 may be configured by an APD as described above. When a reverse bias voltage sufficient to perform the avalanche multiplication operation is supplied to the APD, carriers generated by light incident on the APD cause avalanche multiplication, and an avalanche current is generated. The operation modes in a state where the reverse bias voltage is supplied to the APD include a Geiger mode and a linear mode. The Geiger mode is an operation mode in which a voltage applied between the anode and the cathode is set to a reverse bias voltage larger than the breakdown voltage of the APD. The linear mode is an operation mode in which a voltage applied between the anode and the cathode is set to a reverse bias voltage close to or lower than the breakdown voltage of the APD. An APD that operates in Geiger mode is referred to as SPAD (Single Photon Avalanche Diode). The APD constituting the photoelectric conversion element 22 may be operated in a linear mode or a Geiger mode.

In the present embodiment, the anode of the APD is set to a fixed potential, and a signal is extracted from the cathode side. That is, the semiconductor region of the first conductivity type including the charge of the same polarity as the signal charge as the majority carrier is an n-type semiconductor region, and the semiconductor region of the second conductivity type including the charge of the polarity different from the signal charge as the majority carrier is a p-type semiconductor region. In addition, the first conductivity type carrier is an electron, and the second conductivity type carrier is a hole. The first conductivity type impurity is a donor impurity, and the second conductivity type impurity is an acceptor impurity. Although a case where one node of the APD is set to a fixed potential will be described below, the potentials of both nodes may vary.

On the contrary to the above example, the cathode of the APD may be set to a fixed potential and a signal may be extracted from the anode side. In this case, the semiconductor region of the first conductivity type including the charge of the same polarity as the signal charge as the majority carriers is a p-type semiconductor region, and the semiconductor region of the second conductivity type including the charge of the polarity different from the signal charge as the majority carriers is an n-type semiconductor region. In addition, the first conductivity type carrier is a hole, and the second conductivity type carrier is an electron. The first conductivity type impurity is an acceptor impurity, and the second conductivity type impurity is a donor impurity. In the case of a configuration in which holes are detected as the signal charge, the conductivity types of the semiconductor regions to be described later are opposite to each other.

The quenching element 24 has a function of converting a change in the avalanche current generated in the photoelectric conversion element 22 into a voltage signal. In addition, the quenching element 24 functions as a load circuit (quenching circuit) at the time of signal multiplication by avalanche multiplication and has a function of suppressing avalanche multiplication by reducing a voltage applied to the photoelectric conversion element 22. The operation in which the quenching element 24 suppresses avalanche multiplication is called a quenching operation. The quenching element 24 also has a function of returning the voltage supplied to the photoelectric conversion element 22 to the voltage VH by flowing a current corresponding to the voltage drop due to the quenching operation. The operation of returning the voltage supplied from the quenching element 24 to the photoelectric conversion element 22 to the voltage VH is called a recharge operation. The quenching element 24 may be configured by a resistor element, a MOS transistor, or the like.

The waveform shaping unit 32 includes an input node to which an output signal of the photoelectric conversion unit 20 is input and an output node. The waveform shaping unit 32 has a function of converting an analog signal output from the photoelectric conversion unit 20 into a pulse signal. For example, as illustrated in FIG. 3, the waveform shaping unit 32 may be configured using a NOT circuit (inverter circuit). FIG. 3 illustrates an example in which the waveform shaping unit 32 is configured by one inverter circuit, but the waveform shaping unit 32 may be configured by a circuit in which a plurality of inverter circuits is connected in series. Further, the waveform shaping unit 32 may be configured not only by a NOT circuit but also by other circuits having a waveform shaping effect, such as a logic circuit including a NOR circuit, a NAND circuit, and the like. The output node of the waveform shaping unit 32 is connected to the counter circuit 34.

The counter circuit 34 has an input node to which the output signal of the waveform shaping unit 32 is input, an input node connected to the control line 14, and an output node. The counter circuit 34 has a function of counting pulses superimposed on the signal output from the waveform shaping unit 32 and holding a count value which is a count result. The signal supplied from the vertical scanning circuit unit 40 to the counter circuit 34 via the control line 14 may include an enable signal for controlling a pulse counting period (exposure period), a reset signal for resetting a count value held by the counter circuit 34, and the like. The output node of the counter circuit 34 is connected to the data line 16 via the selection circuit 36.

The selection circuit 36 has a function of switching an electrical connection state (connection or non-connection) between the counter circuit 34 and the data line 16. The selection circuit 36 switches the connection state between the counter circuit 34 and the data line 16 in accordance with a control signal supplied from the vertical scanning circuit unit 40 via the control line 14 (or a control signal supplied from the horizontal scanning circuit unit 60 via the control line 18 in the configuration example of FIG. 2). The selection circuit 36 may include a buffer circuit for outputting a signal.

It is not necessary that each pixel 12 includes the signal processing unit 30, and one pixel signal processing unit 30 may be provided for a plurality of pixels 12. In this case, the signal processing of the plurality of pixels 12 may be sequentially performed using the one pixel signal processing unit 30. When the pixel signal processing unit 30 is configured by the waveform shaping unit 32, the counter circuit 34, and the selection circuit 36, each of the pixel signal processing units 30 does not necessarily include all of the waveform shaping unit 32, the counter circuit 34, and the selection circuit 36.

The photoelectric conversion device 100 according to the present embodiment may be formed on one substrate or may be configured as a stacked-type photoelectric conversion device in which a plurality of substrates is stacked. In the latter case, for example, as illustrated in FIG. 4, the photoelectric conversion device may be configured as a stacked-type photoelectric conversion device in which the sensor substrate 110 and the circuit substrate 180 are stacked and electrically connected to each other. At least the photoelectric conversion element 22 among the constituent elements of the pixel 12 may be disposed on the sensor substrate 110. In addition, among the constituent elements of the pixels 12, the quenching element 24 and the pixel signal processing unit 30 may be disposed on the circuit substrate 180. The photoelectric conversion element 22, the quenching element 24, and the pixel signal processing unit 30 are electrically connected to each other via an interconnection provided for each pixel 12. The circuit substrate 180 may further include a vertical scanning circuit unit 40, a readout circuit unit 50, a horizontal scanning circuit unit 60, an output circuit unit 70, and a control pulse generation unit 80.

The photoelectric conversion element 22, and the quenching element 24 and the pixel signal processing unit 30 of each pixel 12 may be provided on the sensor substrate 110 and the circuit substrate 180 so as to overlap each other in a plan view. The vertical scanning circuit unit 40, the readout circuit unit 50, the horizontal scanning circuit unit 60, the output circuit unit 70, and the control pulse generation unit 80 may be disposed around the pixel region 10 configured by the plurality of pixels 12. Here, the term “plan view” refers to a view from a direction perpendicular to the surface of the sensor substrate 110.

By configuring the stacked-type photoelectric conversion device 100, it is possible to increase the degree of integration of elements and achieve higher functionality. In particular, by arranging the photoelectric conversion element 22, and the quenching element 24 and the pixel signal processing unit 30 on different substrates, the photoelectric conversion element 22 may be arranged at high density without sacrificing the light receiving area of the photoelectric conversion element 22, and the photon detection efficiency may be improved.

The number of substrates constituting the photoelectric conversion device 100 is not limited to two, and three or more substrates may be stacked to constitute the photoelectric conversion device 100.

In FIG. 4, a diced chip is assumed as the sensor substrate 110 and the circuit substrate 180, but the sensor substrate 110 and the circuit substrate 180 are not limited to chips. For example, each of the sensor substrate 110 and the circuit substrate 180 may be a wafer. In addition, the sensor substrate 110 and the circuit substrate 180 may be stacked in a wafer state and then diced or may be stacked and bonded after being formed into chips.

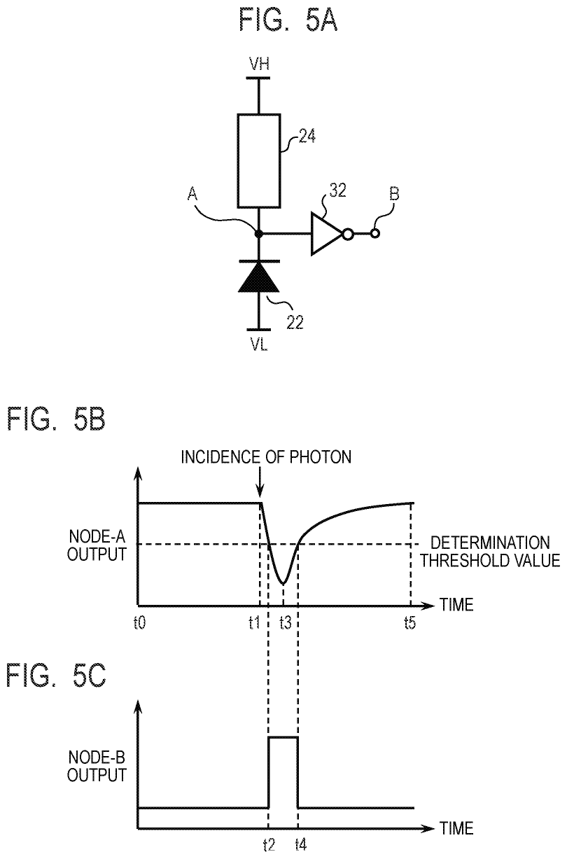

Next, a basic operation of the photoelectric conversion unit 20 in the photoelectric conversion device according to the present embodiment will be described with reference to FIG. 5A, FIG. 5B, and FIG. 5C. FIG. 5A, FIG. 5B, and FIG. 5C are diagrams illustrating the basic operation of the photoelectric conversion unit in the photoelectric conversion device according to the present embodiment. FIG. 5A is a circuit diagram of the photoelectric conversion unit 20 and the waveform shaping unit 32, FIG. 5B illustrates a waveform of a signal at an input node (node-A) of the waveform shaping unit 32, and FIG. 5C illustrates a waveform of a signal at an output node (node-B) of the waveform shaping unit 32.

At time t0, a reverse bias voltage having a potential difference corresponding to VH-VL is applied to the photoelectric conversion element 22. Although a reverse bias voltage sufficient to cause an avalanche multiplication operation is applied between the anode and cathode of the APD constituting the photoelectric conversion element 22, carriers serving as a seed of avalanche multiplication do not exist in a state where photons are not incident on the photoelectric conversion element 22. Therefore, avalanche multiplication does not occur in the photoelectric conversion element 22, and no current flows through the photoelectric conversion element 22.

At the subsequent time t1, it is assumed that a photon is incident on the photoelectric conversion element 22. When a photon enters the photoelectric conversion element 22, an electron-hole pair is generated by photoelectric conversion, avalanche multiplication occurs using these carriers as seeds, and an avalanche multiplication current flows through the photoelectric conversion element 22. When the avalanche multiplication current flows through the quenching element 24, a voltage drop occurs due to the quenching element 24, and the voltage of the node-A starts to drop. When the voltage drop amount of the node-A becomes large and the avalanche multiplication operation is stopped at time t3, the voltage level of the node-A no longer drops.

When the avalanche multiplication operation in the photoelectric conversion element 22 is stopped, a current that compensates for the voltage drop flows from the node to which the voltage VL is supplied to the node-A through the photoelectric conversion element 22, and the voltage of the node-A gradually increases. Thereafter, at time t5, the node-A is settled to the original voltage level.

The waveform shaping unit 32 binarizes the signal input from the node-A according to a predetermined determination threshold value, and outputs the signal from the node-B. Specifically, the waveform shaping unit 32 outputs a low-level signal from the node-B when the voltage level of the node-A exceeds the determination threshold value, and outputs a high-level signal from the node-B when the voltage level of the node-A is equal to or less than the determination threshold value. For example, as illustrated in FIG. 5B, it is assumed that the voltage of the node-A is equal to or lower than the determination threshold value in the period from the time t2 to the time t4. In this case, as illustrated in FIG. 5C, the signal level at the node-B becomes low-level in the period from the time t0 to the time t2 and the period from the time t4 to the time t5 and becomes high-level in the period from the time t2 to the time t4.

In this way, the analog signal input from the node-A is waveform-shaped into a digital signal by the waveform shaping unit 32. A pulse signal output from the waveform shaping unit 32 in response to incidence of a photon on the photoelectric conversion element 22 is a photon detection pulse signal.

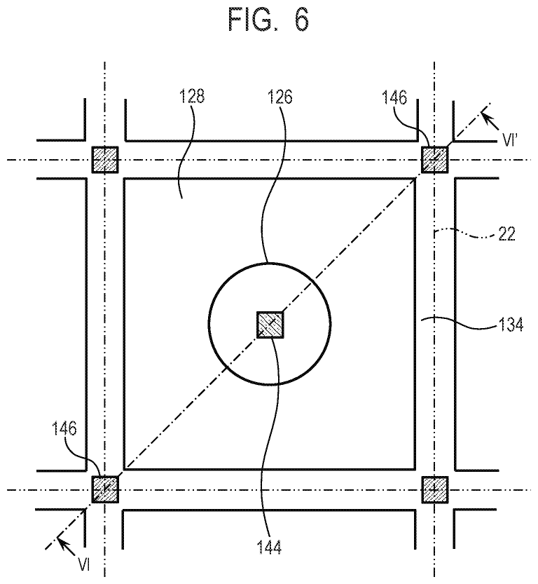

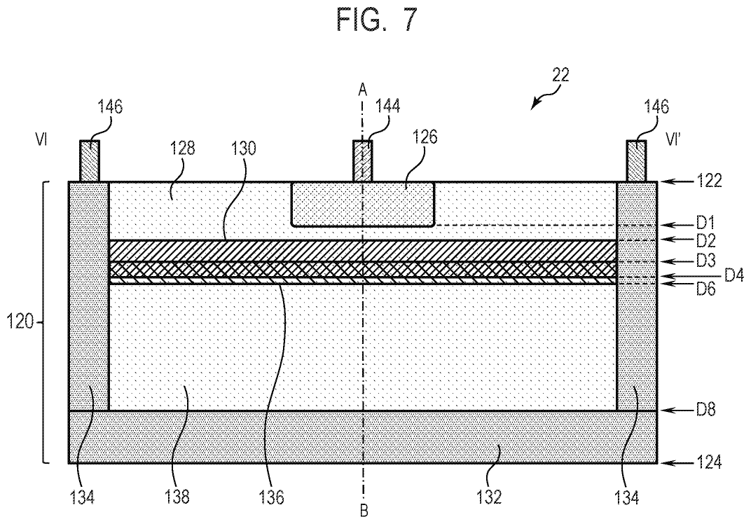

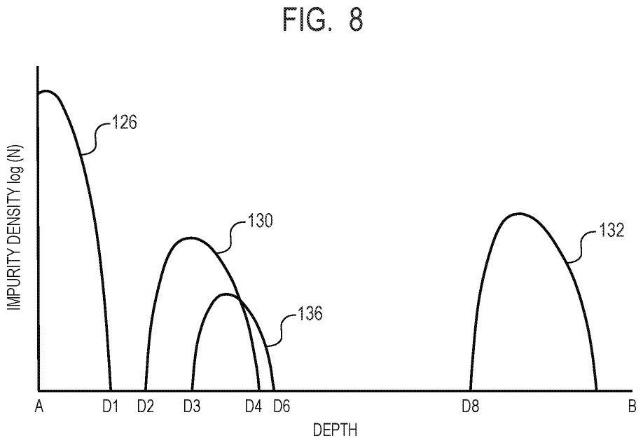

Next, a specific structure of the photoelectric conversion element 22 in the photoelectric conversion device 100 according to the present embodiment will be described with reference to FIG. 6 to FIG. 8. FIG. 6 is a plan view illustrating a structure of the photoelectric conversion element according to the present embodiment. FIG. 7 is a schematic cross-sectional view illustrating the structure of the photoelectric conversion element according to the present embodiment. FIG. 8 is a diagram illustrating distributions of impurity densities in a depth direction in the photoelectric conversion element according to the present embodiment.

The photoelectric conversion element 22 of the photoelectric conversion device 100 according to the present embodiment may be provided in the semiconductor layer 120 included in the sensor substrate 110 in the configuration illustrated in, e.g., FIG. 4. FIG. 6 corresponds to a plan view from the first face 122 side of the semiconductor layer 120. As illustrated in, e.g., FIG. 6, the photoelectric conversion elements 22 of the plurality of pixels 12 configuring the pixel region 10 are arranged in a matrix in the semiconductor layer 120. A two-dot chain line illustrated in FIG. 6 indicates a boundary between adjacent photoelectric conversion elements 22. In this specification, the term “plan view” refers to a view from a normal direction of a surface (a first face 122 to be described later) of the semiconductor layer 120. The term “cross-section” refers to a cross-section parallel to the normal direction of the first face 122 or the second face 124 of the semiconductor layer 120.

FIG. 7 is a cross-sectional view taken along the line VI-VI′ of FIG. 6, and FIG. 8 illustrates a depth distribution of the impurity densities (N) in the semiconductor layer 120 along the line A-B of FIG. 7. In this specification, the depth direction represents a direction from the first face 122 toward the second face 124, and the depth represents a distance from the first face 122.

The semiconductor layer 120 may be a semiconductor layer obtained by thinning a semiconductor substrate having a low impurity density, for example, an n-type silicon substrate having a low impurity density. The semiconductor layer 120 is provided with n-type semiconductor regions 126 and 128, p-type semiconductor regions 130, 132, and 134, an n-type impurity doped region 136, and a semiconductor region 138. Among these regions, FIG. 7 illustrates a density distribution of donor impurities constituting the n-type semiconductor region 126 and the n-type impurity doped region 136 and a density distribution of acceptor impurities constituting the p-type semiconductor regions 130 and 132. The n-type semiconductor region 128 and the semiconductor region 138 have a sufficiently low impurity density as compared with the n-type semiconductor region 126, the p-type semiconductor regions 130 and 132, and the n-type impurity doped region 136 and a small influence on them, and thus are not illustrated. The cathode electrode 144 electrically connected to the n-type semiconductor region 126 and the anode electrode 146 electrically connected to the p-type semiconductor region 134 are provided on the first face 122 of the semiconductor layer 120.

The n-type semiconductor region 126 is provided from the first face 122 to a depth D1 so that at least a part thereof reaches the first face 122. The n-type semiconductor region 128 is provided from the first face 122 to a depth D2 deeper than the depth D1 so as to surround the n-type semiconductor region 126. The p-type semiconductor region 130 is provided from the depth D2 to a depth D4 deeper than the depth D2. The n-type impurity doped region 136 is provided from a depth D3 deeper than the depth D2 and shallower than the depth D4 to a depth D6 deeper than the depth D4. The semiconductor region 138 is provided from the depth D6 to a depth D8 deeper than the depth D6. The p-type semiconductor region 132 is provided from the depth D8 to the second face 124. The p-type semiconductor region 134 is disposed so as to surround the region in which the n-type semiconductor regions 126 and 128, the p-type semiconductor region 130, the n-type impurity doped region 136, and the semiconductor region 138 are provided in a plan view (see FIG. 6). The p-type semiconductor region 134 is disposed from the first face 122 to the depth D8 and is electrically connected to the p-type semiconductor region 132. A region in the semiconductor layer 120 surrounded by the p-type semiconductor regions 132 and 134 is a region in which one photoelectric conversion element 22 is disposed. Here, this region is referred to as a well region.

The n-type semiconductor region 126 is an n-type semiconductor region having high impurity density and serving as cathode of the APD constituting the photoelectric conversion element 22 and is disposed in the central portion of the well region in the plan view as illustrated in FIG. 6. The cathode electrode 144 is provided on the n-type semiconductor region 126. The cathode electrode 144 forms an ohmic contact with the n-type semiconductor region 126. The n-type semiconductor region 128 is an n-type semiconductor region having a lower impurity density than the n-type semiconductor region 126 and is provided over the entire well region in the plan view. The p-type semiconductor region 130 is a p-type semiconductor region serving as anode of the APD constituting the photoelectric conversion element 22. The p-type semiconductor region 130 is provided over the entire well region in the plan view and is electrically connected to the p-type semiconductor region 134 at the peripheral edge portion in the plan view. As illustrated in FIG. 7, the n-type impurity-doped region 136 is provided over the entire well region in the plan view so as to overlap a tail portion on the side of the second face 124 of the p-type semiconductor region 130 in the impurity density distribution. In other words, the peak position of the impurity density of the donor impurity constituting the n-type impurity doped region 136 is located deeper than the peak position of the impurity density of the acceptor impurity constituting the p-type semiconductor region 130. The donor impurity density constituting the n-type impurity doped region 136 is lower than the acceptor impurity density constituting the p-type semiconductor region 130. The semiconductor region 138 is a semiconductor region having a low impurity density serving as a photoelectric conversion region and may be an n-type semiconductor region or a p-type semiconductor region. The p-type semiconductor region 132 has a function of defining the depth of the photoelectric conversion region. In addition, the p-type semiconductor region 132, together with the p-type semiconductor region 134, also serves as an isolation region that isolates adjacent photoelectric conversion elements 22. The p-type semiconductor region 134 has a p-type semiconductor region (not illustrated) having a high impurity density at least in a portion in contact with the first face 122 and is in ohmic contact with the anode electrode 146.

The photoelectric conversion element 22 of the photoelectric conversion device 100 according to the present embodiment may be manufactured by using a general method of manufacturing semiconductor devices. For example, each semiconductor region and the n-type impurity doped region 136 are formed by using photolithography and ion implantation from the side of one surface (the side of the first face 122) of the n-type silicon substrate having low impurity density. Next, the interconnection layer including the cathode electrode 144 and the anode electrode 146 is formed on the one surface of the n-type silicon substrate. Next, the n-type silicon substrate is thinned from the other surface side of the n-type silicon substrate to form the semiconductor layer 120. The new surface exposed by thinning the n-type silicon substrate becomes the second face 124.

For example, the n-type semiconductor region 126 is formed by ion-implanting a donor impurity so as to be in contact with the first face 122 of the semiconductor layer 120. The p-type semiconductor region 130 is formed by ion-implanting acceptor impurity deeper than the depth at which the n-type semiconductor region 126 is provided. The semiconductor region 138 may be formed by ion-implanting impurities deeper than the depth at which the p-type semiconductor region 130 is provided, or an n-type silicon substrate may be used as it is. The n-type impurity doped region 136 is formed so as to overlap the p-type semiconductor region 130 in the depth direction of the semiconductor layer 120. In addition, the n-type impurity doped region 136 is formed by ion-implanting the donor impurity so that the depth at which the density of the donor impurity reaches the peak is located deeper than the depth at which the density of the acceptor impurity constituting the p-type semiconductor region 130 reaches the peak.

When the side of the second face 124 of the semiconductor layer 120 is a light receiving surface on which light to be detected is incident, as illustrated in FIG. 7, the p-type semiconductor region 132 is preferably formed so as to be in contact with the second face 124. By configuring the p-type semiconductor region 132 in this manner, it is possible to prevent generation of dark current on the second face 124. In addition, the dielectric isolation structure using a deep trench may be used as an isolation region for isolating adjacent photoelectric conversion elements 22. In this case, the p-type semiconductor region 134 may be disposed around the isolation dielectric.

In the photoelectric conversion element 22 of the present embodiment, avalanche multiplication of the signal charge occurs between the n-type semiconductor region 126 and the p-type semiconductor region 130 opposed thereto. On the other hand, the distance between the n-type semiconductor region 126 and the p-type semiconductor region 134 is much longer than the distance between the n-type semiconductor region 126 and the p-type semiconductor region 130. In addition, the impurity density of the n-type semiconductor region 128 is low. Therefore, electric field concentration does not occur in the lateral direction (direction parallel to the first face 122) from the n-type semiconductor region 126 toward the p-type semiconductor region 134. That is, the electric field intensity in the lateral direction is not so strong as to cause the avalanche multiplication action, and the avalanche multiplication is not caused by the electric field in the lateral direction. Therefore, even if dark electrons are generated in the vicinity of the first face 122, the dark electrons do not cause avalanche multiplication by the electric field in the lateral direction, and the dark electrons are not detected as noise.

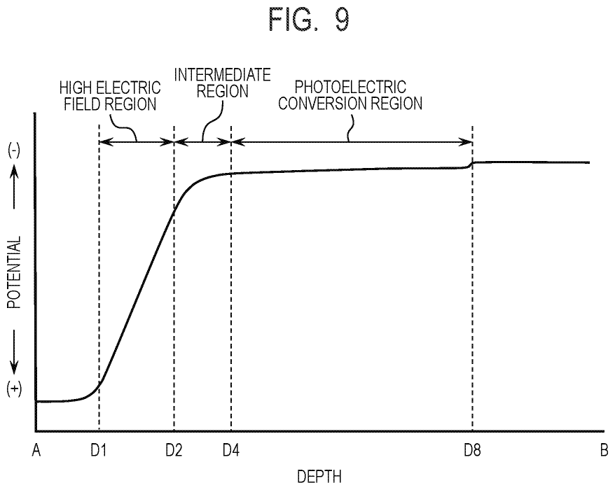

FIG. 9 is the diagram illustrating potential distribution in the semiconductor layer 120 along the line A-B in FIG. 7. The vertical axis indicates a potential with respect to electrons which are signal charge carriers, and the higher the vertical axis, the higher the potential energy of electrons, that is, the lower the potential (voltage) and the lower the vertical axis, the lower the potential energy of electrons, that is, the higher the potential (voltage). Line A-B in FIG. 7 is a line that is orthogonal to the first face 122 and the second face 124 and passes through the center of the n-type semiconductor region 126 and overlaps with a main path through which the signal charge (electrons) generated in the semiconductor region 138 flows toward the n-type semiconductor region 126.

The photoelectric conversion element 22 of the present embodiment is basically divided into the high electric field region in which avalanche multiplication occurs and the photoelectric conversion region in which signal carriers generate. Specifically, along the line A-B in FIG. 7, the region from the n-type semiconductor region 126 to the p-type semiconductor region 130 is the high electric field region, and the region from the p-type semiconductor region 130 to the p-type semiconductor region 132 is the photoelectric conversion region.

The signal charge generated in the photoelectric conversion region moves along the potential gradient to the high electric field region by drift or the like, causes avalanche multiplication, and is collected through the cathode electrode 144 to be detected as a signal. Although the p-type semiconductor region 130 is an intermediate region between the photoelectric conversion region and the high electric field region, at least a portion of the p-type semiconductor region 130 along the line A-B needs to be completely depleted in order to obtain the potential distribution illustrated in FIG. 9. At least most of the semiconductor region 138 having a low impurity density is also depleted. The above-described structure is referred to as a charge collecting-type APD.

Here, the drive voltage applied to the charge collecting-type APD (voltage applied between the cathode electrode 144 and the anode electrode 146) is referred to as a drive voltage VDD. At this time, when voltages applied to each of the high electric field region, the intermediate region, and the photoelectric conversion region along the line A-B are a voltage V1, a voltage V2, and a voltage V3, respectively, the drive voltage VDD is expressed as follows.

VDD=V1+V2+V3

More specifically, on the line A-B, the n-type semiconductor region 126 and the p-type semiconductor region 132 are neutral regions that are not depleted, and all regions therebetween are depleted. Therefore, the drive voltage VDD applied along the line A-B becomes the potential difference between the n-type semiconductor region 126 and the p-type semiconductor region 132, and the potential distribution of the region therebetween is determined by the impurity distribution of the region therebetween. That is, each of the voltage V1, the voltage V2, and the voltage V3 is determined by the impurity distribution in the region on the A-B line. Here, the high electric field region is from the n-type semiconductor region 126 to the p-type semiconductor region 130. The intermediate region is the p-type semiconductor region 130. Further, the photoelectric conversion region is from the p-type semiconductor region 130 to the p-type semiconductor region 132. Referring to FIG. 8, the voltage V1 and the voltage V2 are higher than the voltage V3 due to the impurity density distribution. As described above, the drive voltage VDD is the sum of these voltages. The potential of the p-type semiconductor region 132 is higher than the potential of the p-type semiconductor region 130 due to the relationship of the impurity density distribution illustrated in FIG. 8.

The voltage V1 is a voltage required to generate avalanche multiplication. When the voltage V1 is equal to or higher than the voltage required for avalanche multiplication in the high electric field region, the SPAD operation may be performed, but when the values of the voltages V2 and V3 are insufficient, a decrease in quantum efficiency and an increase in signal response time are caused, and consequently, signal performance deteriorates. Therefore, in the charge collecting-type APD, it is also necessary to sufficiently consider the voltage V2 and the voltage V3.

Of the voltage V1, the voltage V2, and the voltage V3, the voltage V3 directly relates to the time until the signal electrons generated in the photoelectric conversion region reach the high electric field region, that is, the signal response time, and is substantially determined according to the application. Therefore, in order to realize the low voltage operation of the photoelectric conversion element 22, it is important how to reduce the voltage V1 and the voltage V2.

First, a method for reducing the voltage V2 is described.

As the voltage V2, in addition to the voltage required to completely deplete the p-type semiconductor region 130 along the A-B line, the voltage required to eliminate the potential barrier at the boundary between the intermediate region and the photoelectric conversion region along the A-B line is required.

Since a high electric field sufficient to cause avalanche multiplication must be formed between the n-type semiconductor region 126 and the p-type semiconductor region 130, the p-type semiconductor region 130 needs to have an effective impurity density of a certain value or more. Here, the effective impurity density is a net impurity density expressed as a difference between the acceptor impurity density and the donor impurity density when both the acceptor impurity and the donor impurity exist. In the present specification, in order to clarify a main impurity determining the conductivity type, an effective impurity density of a p-type semiconductor region when the donor impurity is included in the p-type semiconductor region may be referred to as an effective acceptor density. An effective impurity density of the n-type semiconductor region when the acceptor impurity is included in the n-type semiconductor region may be referred to as an effective donor density.

According to the semiconductor theory, assuming that an effective impurity density of a semiconductor layer is A and a width thereof is W, and an impurity density per unit area (A×W) is a constant value, a voltage required to deplete the semiconductor layer is proportional to W. That is, when the impurity is distributed in a narrower width range, the depletion voltage becomes small. Therefore, in order to make the voltage V2 as small as possible, it is desirable to make the width of the p-type semiconductor region 130 in the depth direction as narrow as possible.

In general, boron is used as an acceptor impurity for forming the p-type semiconductor region. In order to dope impurities to a semiconductor, ion implantation is often used in which density and depth may be easily controlled. In the case where an impurity is doped to a semiconductor by ion implantation, a phenomenon in which ions proceed along a crystal axis or a crystal plane, so-called channeling occurs, and a broad impurity distribution may occur in the depth direction. In particular, channeling is likely to occur when ions having a small atomic mass such as boron are used. Therefore, when forming the p-type semiconductor region 130 in which the width in the depth direction is required to be narrowed, it is preferable to perform ion implantation from a direction having a certain degrees of angle with respect to the crystal axis.

In addition, the effective width of the p-type semiconductor region 130 may be narrowed by providing the n-type impurity doped region 136 so as to overlap with the tail portion on the side of the second face 124 of the p-type semiconductor region 130 in the impurity density distribution. When the n-type impurity doped region 136 is provided, a part of the acceptor impurity of the p-type semiconductor region 130 is compensated by the donor impurity of the n-type impurity doped region 136, and the effective impurity density of the p-type semiconductor region 130 decreases. Therefore, the amount of the acceptor impurity introduced per unit area when the p-type semiconductor region 130 is formed may be increased as compared with the case where the n-type impurity doped region 136 is not formed so that the p-type semiconductor region 130 having an effective impurity density equal to or higher than the predetermined value may be obtained.

By configuring the photoelectric conversion element 22 in this manner, the effective width of the p-type semiconductor region 130 may be narrowed, and the value of the voltage V2 may be reduced.

Next, a method for reducing the voltage V1 will be described.

Whether or not avalanche multiplication occurs in the high electric field region depends on how much impact ionization occurs in signal charge carriers traveling in the high electric field region. Here, assuming that the electric field intensity in the high electric field region is constant, the impact ionization rate which is the number of impact ionization occurrences per unit length is a, and the width of the high electric field region in the depth direction is W1, the probability of causing avalanche multiplication increases as the value of α×W1 increases. Therefore, in order to set the occurrence probability of avalanche multiplication to a sufficient value, it is necessary to set the value of α×W1 to a certain value or more. Note that the value actually required as α×W1 is about 2.

Among the parameters for determining the occurrence probability of avalanche multiplication, the impact ionization rate a largely depends on the electric field intensity in the high electric field region, that is, V1/W1. The electric field intensity in the high electric field region in the normal SPAD is about 400 kV/cm to 600 kV/cm. On the other hand, if the width W1 of the high electric field region is changed from W1 to W1-ΔW, the impact ionization rate a increases exponentially as ΔW increases. That is, the smaller the value of W1, the larger the value of α×W1. In other words, by reducing the width W1, the voltage V1 may be reduced while maintaining the value of α×W1.

For more quantitative discussion, the width W1 is defined as follows. That is, the width W1 is defined as a width from a depth at which the effective donor density of the n-type semiconductor region 126 becomes 1×10¹⁶ cm⁻³ to a depth at which the effective acceptor density of the p-type semiconductor region 130 becomes 1×10¹⁶ cm⁻³ on the side of the first face 122 (the tail on the side of the first face 122).

In general, the electric field intensity when a reverse bias voltage is applied to the p-n junction decreases in depletion regions on both sides of the p-n junction face with the p-n junction face as a peak. This is because electrostatic shielding is caused by charges of impurity ions when the semiconductor regions are depleted. However, when the density of impurity ions is about 1×10¹⁶ cm⁻³ or less, the influence of the electrostatic shielding is relatively small. Moreover, in the region between the n-type semiconductor region 126 and the p-type semiconductor region 130, the acceptor and the donor largely cancel each other out particularly at a density of 1×10¹⁶ cm⁻³ or less. Therefore, the effective donor density distribution and the effective acceptor density distribution become very steep at about 1×10¹⁶ cm⁻³ or less, and the influence on the electric field intensity becomes smaller. Therefore, the width W1 defined as described above may be regarded as a high electric field region that maintains a substantially constant electric field intensity.

Similarly, the width W2 of the p-type semiconductor region 130 in the depth direction is defined as follows. That is, the width W2 is defined as a width from the depth on the side of the first face 122 where the effective acceptor density of the p-type semiconductor region 130 is 1×10¹⁶ cm⁻³ to the depth on the side of the second face 124 where the effective acceptor density of the p-type semiconductor region 130 is 1×10¹⁶ cm⁻³.

In the photoelectric conversion element 22 of the present embodiment, for example, the target of the drive voltage VDD is 25 V or less. A configuration example of the width W1, the width W2, and the effective acceptor density NA of the p-type semiconductor region 130 for achieving this target will be calculated below.

First, the voltage V2, the width W2, and the effective acceptor density NA of the p-type semiconductor region 130 will be considered. When the built-in voltage is Vb, the elementary charge amount is q, and the dielectric constant of the semiconductor is &, the voltage V2 is expressed by the following Expression (1).

$$V 2 = qNA / ( 2 ε ) \times ( W {2}^{2} ) - Vb \qquad ( 1 )$$

Assuming that the width W2 is 0.6 μm, the effective acceptor density NA is 4×10¹⁶ cm⁻³, and the built-in voltage Vb is 0.7 V, the voltage V2 is calculated as 10.3 V from Expression (1).

When the width W2 is set to 0.4 μm and the effective acceptor density NA is set to 6×10¹⁶ cm⁻³ without changing the value of W2×NA, the voltage V2 is calculated as 6.6 V from Expression (1). As described above, by changing the relationship between the width W2 and the effective acceptor density NA from the former condition to the latter condition, the value of the voltage V2 decreases by 3.7 V.

Although the effective acceptor density NA actually has a distribution in a region of width W2, the average effective acceptor density in the region of width W2 is used here for simplification. Further, when the value of W2×NA is low, the value of the voltage V2 also becomes small, but when the value of W2×NA is too low, punch-through occurs in the p-type semiconductor region 130 when the reverse bias voltage of high electric field is applied to the APD, and the electric field intensity of the high electric field region cannot be kept high. Therefore, the value of W2×NA needs to have a certain value or more. In the above calculation example, the value of W2×NA is 2.4×10¹² cm⁻², which is an effective acceptor density offset to some extent by the donor impurity and is a value in a density range of 1× 10¹⁶ cm⁻³ or more. Therefore, in order to form the p-type semiconductor region 130, it is necessary to introduce an acceptor impurity of 3×10¹² cm⁻² or more.

Next, the voltage V1 and the width W1 necessary for generating avalanche multiplication will be considered. As described above, the value of α×W1 is required to be about 2 or more. Therefore, when the width W1 is, for example, 0.4 μm, the impact ionization rate a is required to be 5×10⁴/cm or more. When the signal charge carriers are electrons, the electric field intensity at which the impact ionization rate a becomes 5×10⁴/cm is 400 kV/cm. Therefore, when the width W1 is 0.4 μm, 16 V is required as the voltage V1.

As described above, when the width W1 is 0.4 μm, the width W2 is 0.4 μm, and the effective acceptor density NA is 6×10¹⁶ cm⁻³, the voltage V1 is 16 V and the voltage V2 is 6.6 V. The voltage V3 is usually about 1 V to 5 V, depending on the requirements of the signal response speed. Therefore, when the voltage V3 is 2.4 V, the drive voltage VDD is V1+V2+V3=25 V.

From the above example, it can be understood that it is important to reduce the width W1 and the width W2 with respect to the subject of reducing the drive voltage VDD. As a result of further studying other various conditions, it was found that it is important to set the value of (W1+W2) to 0.8 μm or less. If the width W2 is set to 0.5 μm, the voltage V2 becomes large, and thus the width W1 is required to be set to 0.3 μm or less in order to reduce the voltage V1.

In addition, in order to reduce the width W2, it is important that the n-type impurity doped region 136 is provided so as to exactly compensate the tail portion of the acceptor impurity density distribution of the p-type semiconductor region 130. The donor amount per unit area necessary for the formation of the n-type impurity doped region 136 may be about one half or less of the acceptor amount per unit area necessary for the formation of the p-type semiconductor region 130 according to the trial of the present inventor, but at least about 5×10¹¹ cm⁻² is necessary. It is actually difficult to set the width W2 to 0.5 μm or less, that is, to set (W1+W2) to 0.8 μm or less without the n-type impurity doped region 136 of such a degree.

As described above, according to the present embodiment, the drive voltage of the avalanche photodiode may be reduced. As a result, it is possible to realize energy saving due to low power consumption, to alleviate deterioration in element characteristics due to reduction in heat generation, to reduce dark current, and the like.

### Second Embodiment

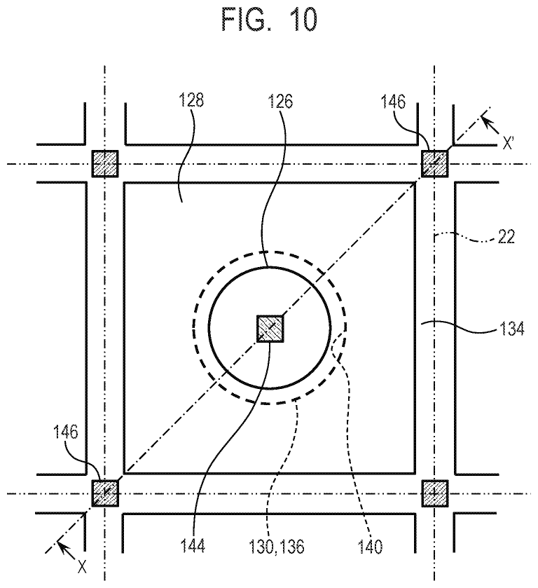

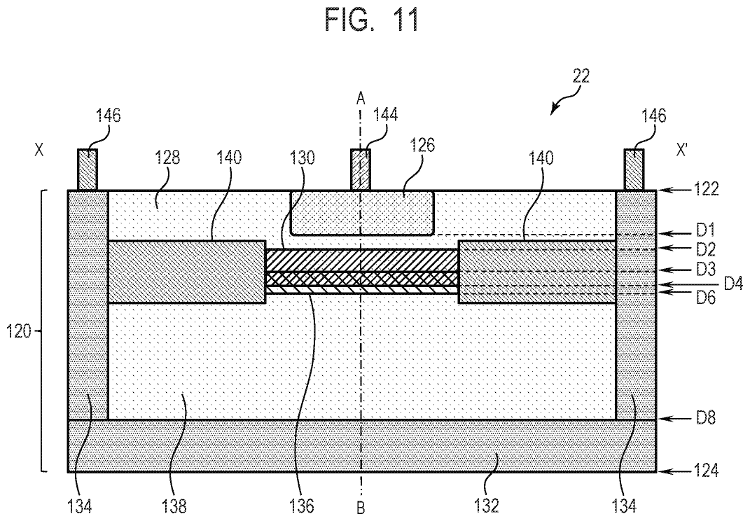

A photoelectric conversion device according to a second embodiment of the present invention will be described with reference to FIG. 10 and FIG. 11. The same components as those of the photoelectric conversion device according to the first embodiment are denoted by the same reference numerals, and description thereof will be omitted or simplified. FIG. 10 is a plan view illustrating a structure of a photoelectric conversion element in the photoelectric conversion device according to the present embodiment. FIG. 11 is a schematic cross-sectional view illustrating a structure of the photoelectric conversion element in the photoelectric conversion device according to the present embodiment.

The photoelectric conversion device according to the present embodiment is the same as the photoelectric conversion device according to the first embodiment except that the configuration of the photoelectric conversion element 22 is different. In the present embodiment, portions of the photoelectric conversion element 22 of the present embodiment different from the photoelectric conversion element 22 of the first embodiment will be mainly described, and description of portions common to the photoelectric conversion element 22 of the first embodiment will be appropriately omitted.

The photoelectric conversion element 22 of the present embodiment further includes a p-type semiconductor region 140 in addition to the n-type semiconductor regions 126 and 128, the p-type semiconductor regions 130, 132, and 134, the n-type impurity doped region 136, and the semiconductor region 138.

In the photoelectric conversion element 22 of the first embodiment, the p-type semiconductor region 130 and the n-type impurity-doped region 136 are provided over the entire well region in the plan view. On the other hand, in the photoelectric conversion element 22 of the present embodiment, as illustrated in FIG. 11, the p-type semiconductor region 130 and the n-type impurity-doped region 136 are disposed in the central portion of the well region in a plan view so as to overlap the n-type semiconductor region 126 in the plan view. A p-type semiconductor region 140 is provided between the p-type semiconductor region 134, and the p-type semiconductor region 130 and the n-type impurity doped region 136 in the plan view. The p-type semiconductor region 130 is electrically connected to the anode electrode 146 via the p-type semiconductor region 140 and the p-type semiconductor region 134. The effective acceptor density per unit area of the p-type semiconductor region 140 is higher than the effective acceptor density per unit area of the p-type semiconductor region 130.

In the photoelectric conversion element 22 of the first embodiment, there is a possibility that electrons generated in the semiconductor region 138 which is a photoelectric conversion region may reach the n-type semiconductor region 128 beyond the p-type semiconductor region 130 in the peripheral portion of the well region in the plan view. In this case, since electrons reaching the n-type semiconductor region 128 in the peripheral portion of the well region do not cause avalanche multiplication as described above and are not detected as a signal, sensitivity loss occurs.

By further providing the p-type semiconductor region 140 in the peripheral portion of the well region in the plan view, the potential barrier between the semiconductor region 138 and the n-type semiconductor region 128 in the peripheral portion of the well region in the plan view becomes larger. Thus, electrons generated in the semiconductor region 138, which is the photoelectric conversion region, more easily reach the n-type semiconductor region 128 beyond the p-type semiconductor region 130 in the central portion than reach the n-type semiconductor region 128 beyond the p-type semiconductor region 140 in the peripheral portion. When a signal electron passes through such a path, avalanche multiplication occurs when the signal electron passes through a high electric field region, and the signal electron may be detected as a signal.

Therefore, according to the photoelectric conversion element 22 of the present embodiment, as compared with the photoelectric conversion element of the first embodiment, it is possible to increase the proportion of the signal electrons reaching the cathode through the center portion of the photoelectric conversion element 22, that is, the vicinity of the line A-B passing through the center of the cathode. As a result, the photo-sensitivity may be improved.

In FIG. 11, the p-type semiconductor region 140 is provided from a depth deeper than the depth D1 and shallower than the depth D2 to a depth deeper than the depth D6 and shallower than the depth D8, but the depth at which the p-type semiconductor region 140 is provided is not limited thereto. The p-type semiconductor region 140 may have at least an effective acceptor density per unit area higher than the effective acceptor density per unit area of the p-type semiconductor region 130 and may be electrically connected to the p-type semiconductor region 130 and the p-type semiconductor region 134.

The p-type semiconductor region 140 may be formed by various methods. For example, the p-type semiconductor region 140 may be formed by additionally introducing an acceptor impurity to the periphery of the well region in the structure of the first embodiment. Alternatively, in the structure of the first embodiment, the n-type impurity doped region 136 may be formed only in the central portion of the well region, and the p-type semiconductor region 130 in the peripheral portion of the well region not overlapping the n-type impurity doped region 136 may be substantially the p-type semiconductor region 140. Alternatively, in the structure of the first embodiment, the acceptor impurity of the p-type semiconductor region 130 in the central portion of the well region may be partially compensated by the donor impurity of the n-type semiconductor region 126 or an n-type semiconductor region additionally formed. In this case, the p-type semiconductor region 130 in the peripheral portion of the well region where the acceptor impurity is not partially compensated by the donor impurity substantially becomes the p-type semiconductor region 140.

When the p-type semiconductor region 130 and the p-type semiconductor region 140 are considered as one p-type semiconductor region, it can be said that the p-type semiconductor region has a first region overlapping the n-type semiconductor region 126 in a plan view and a second region not overlapping the n-type semiconductor region 126 in the plan view. In this case, the effective impurity density per unit area of the acceptor impurity constituting the second region is higher than the effective impurity density per unit area of the acceptor impurity constituting the first region. The second region is typically a region surrounding the first region.

As described above, according to the present embodiment, in addition to the effects described in the first embodiment, a further effect of improving sensitivity may be achieved.

### Third Embodiment

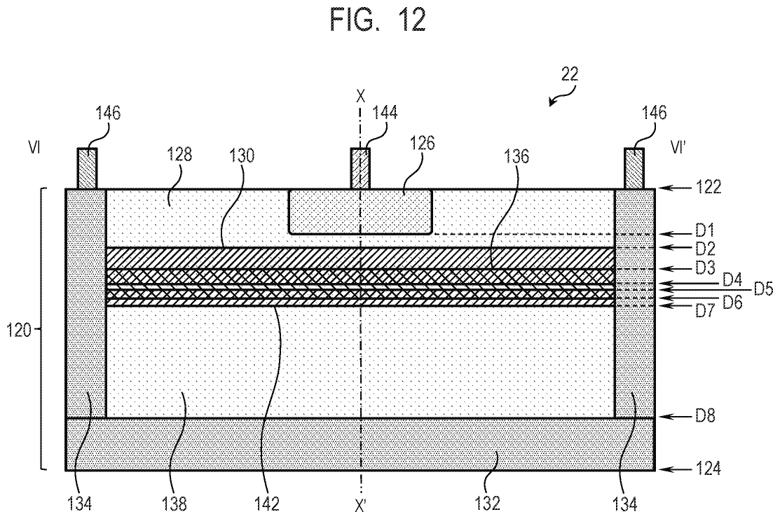

A photoelectric conversion device according to a third embodiment of the present invention will be described with reference to FIG. 12. The same components as those of the photoelectric conversion device according to the first or second embodiment are denoted by the same reference numerals, and description thereof will be omitted or simplified. FIG. 12 is a schematic cross-sectional view illustrating a structure of a photoelectric conversion element in the photoelectric conversion device according to the present embodiment.

The photoelectric conversion device according to the present embodiment is the same as the photoelectric conversion device according to the first embodiment except that the configuration of the photoelectric conversion element 22 is different. In the present embodiment, portions of the photoelectric conversion element 22 of the present embodiment different from the photoelectric conversion element 22 of the first embodiment will be mainly described, and description of portions common to the photoelectric conversion element 22 of the first embodiment will be appropriately omitted.

The photoelectric conversion element 22 of the present embodiment further includes a p-type impurity doped region 142 in addition to the n-type semiconductor regions 126 and 128, the p-type semiconductor regions 130, 132, and 134, the n-type impurity doped region 136, and the semiconductor region 138. The p-type impurity doped region 142 is provided from a depth D5 between the depth D4 and the depth D6 to a depth D7 between the depth D6 and the depth D8. More specifically, the p-type impurity-doped region 142 is provided over the entire well region in a plan view so as to overlap the tail portion on the side of the second face 124 of the n-type impurity doped region 136 in the impurity density distribution. In other words, the peak position of the impurity density of the acceptor impurity constituting the p-type impurity doped region 142 is located deeper than the peak position of the impurity density of the donor impurity constituting the n-type impurity doped region 136. The p-type impurity doped region 142 is formed at impurity density that compensates for the donor impurity in the tail portion on the side of the second face 124 of the n-type impurity doped region 136 in the impurity density distribution. Typically, the impurity density of the p-type impurity doped region 142 is lower than the impurity density of the n-type impurity doped region 136.

The p-type impurity doped region 142 is formed so as to overlap the n-type impurity doped region 136 in the depth direction of the semiconductor layer 120. In addition, the p-type impurity doped region 142 is formed by ion-implanting the acceptor impurity so that the depth at which the density of the acceptor impurity reaches the peak is located closer to the second face 124 than the depth at which the density of the donor impurity constituting the n-type impurity doped region 136 reaches the peak.

By providing the n-type impurity doped region 136, the potential with respect to electrons is lowered, so that a so-called potential pocket is easily formed. If there is a potential pocket, the signal electrons are likely to stay in the potential pocket, the time until the signal electrons reach the high electric field region becomes long, and the response performance of the signal deteriorates. By further providing the p-type impurity doped region 142, it is possible to prevent the formation of the above-described potential pocket, and it is possible to reduce a decrease in the moving speed of signal electrons due to the provision of the n-type impurity doped region 136.

In addition to the above configuration of the present embodiment, the p-type semiconductor region 140 described in the second embodiment may be further added.

As described above, according to the present embodiment, in addition to the effects described in the first and second embodiments, it is possible to realize a further effect of improving signal responsiveness.

### Fourth Embodiment

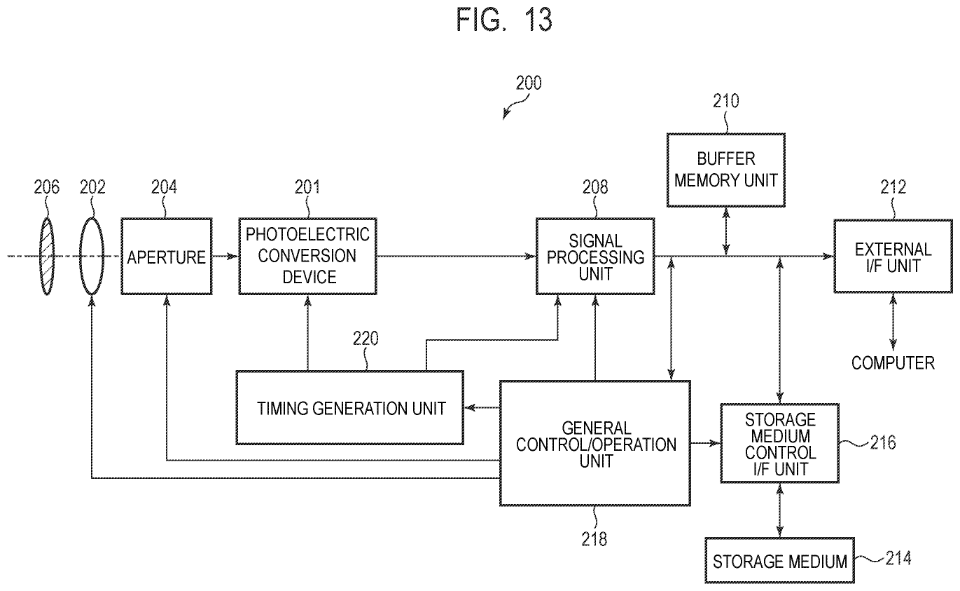

A photodetection system according to a fourth embodiment of the present invention will be described with reference to FIG. 13. FIG. 13 is a block diagram illustrating a schematic configuration of a photodetection system according to the present embodiment. In the present embodiment, a photodetection sensor to which the photoelectric conversion device 100 according to any of the first to third embodiments is applied will be described.

The photoelectric conversion device 100 described in the first to third embodiments may be applied to various photodetection systems. Examples of applicable photodetection systems include imaging systems such as digital still cameras, digital camcorders, surveillance cameras, copying machines, facsimiles, mobile phones, on-vehicle cameras, observation satellites, and the like. A camera module including an optical system such as a lens and an imaging device is also included in the photodetection system. FIG. 13 exemplifies a block diagram of a digital still camera as one of these.

The photodetection system 200 illustrated in FIG. 13 includes a photoelectric conversion device 201, a lens 202 that forms an optical image of an object on the photoelectric conversion device 201, an aperture 204 for varying an amount of light passing through the lens 202, and a barrier 206 for protecting the lens 202. The lens 202 and the aperture 204 form an optical system that focuses light onto the photoelectric conversion device 201. The photoelectric conversion device 201 is the photoelectric conversion device 100 described in any of the first to third embodiments and converts the optical image formed by the lens 202 into image data.

The photodetection system 200 further includes a signal processing unit 208 that processes an output signal output from the photoelectric conversion device 201. The signal processing unit 208 generates image data from the digital signal output from the photoelectric conversion device 201. Further, the signal processing unit 208 performs various corrections and compressions as necessary and outputs the processed image data. The photoelectric conversion device 201 may include an AD conversion unit that generates a digital signal to be processed by the signal processing unit 208. The AD conversion unit may be formed on a semiconductor layer (semiconductor substrate) on which the photoelectric conversion element of the photoelectric conversion device 201 is formed or may be formed on a semiconductor layer different from the semiconductor layer on which the photoelectric conversion element of the photoelectric conversion device 201 is formed. The signal processing unit 208 may be formed on the same semiconductor layer as the photoelectric conversion device 201.

The photodetection system 200 further includes a buffer memory unit 210 for temporarily storing image data, and an external interface unit (external I/F unit) 212 for communicating with an external computer or the like. Further, the photodetection system 200 includes a storage medium 214 such as a semiconductor memory for performing storing or reading out of imaging data, and a storage medium control interface unit (storage medium control I/F unit) 216 for performing storing on or reading out from the storage medium 214. The storage medium 214 may be built in the photodetection system 200 or may be detachable. Communication between the storage medium control I/F unit 216 and the storage medium 214 and communication from the external I/F unit 212 may be performed wirelessly.

The photodetection system 200 further includes a general control/operation unit 218 that performs various calculations and controls the entire digital still camera, and a timing generation unit 220 that outputs various timing signals to the photoelectric conversion device 201 and the signal processing unit 208. Here, the timing signal or the like may be input from the outside, and the photodetection system 200 may include at least the photoelectric conversion device 201 and the signal processing unit 208 that processes the output signal output from the photoelectric conversion device 201. The timing generation unit 220 may be mounted on the photoelectric conversion device 201. Further, the general control/operation unit 218 and the timing generation unit 220 may be configured to perform a part or all of the control functions of the photoelectric conversion device 201.

The photoelectric conversion device 201 outputs an imaging signal to the signal processing unit 208. The signal processing unit 208 performs predetermined signal processing on the imaging signal output from the photoelectric conversion device 201, and outputs the processed image data. The signal processing unit 208 generates an image using the imaging signal. The signal processing unit 208 may be configured to perform distance measurement calculation on the signal output from the photoelectric conversion device 201.

As described above, according to the present embodiment, by configuring the photodetection system using the photoelectric conversion devices according to the first to third embodiments, it is possible to realize the photodetection system capable of acquiring a higher quality image.

### Fifth Embodiment

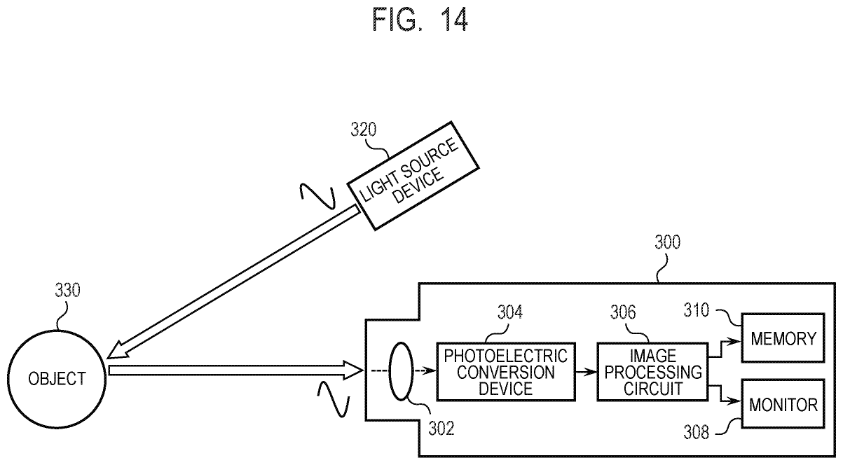

A range image sensor according to a fifth embodiment of the present invention will be described with reference to FIG. 14. FIG. 14 is a block diagram illustrating a schematic configuration of a range image sensor according to the present embodiment. In the present embodiment, a range image sensor will be described as an example of a photodetection system to which the photoelectric conversion device 100 described in any of the first to third embodiments is applied.

As illustrated in FIG. 14, the range image sensor 300 according to the present embodiment may include an optical system 302, a photoelectric conversion device 304, an image processing circuit 306, a monitor 308, and a memory 310. The range image sensor 300 receives light (modulated light or pulsed light) emitted from a light source device 320 toward an object 330 and reflected on the surface of the object 330 and acquires a distance image corresponding to the distance to the object 330.

The optical system 302 includes one or a plurality of lenses and has a function of forming an image of image light (incident light) from the object 330 on a light receiving surface (sensor unit) of the photoelectric conversion device 304.

The photoelectric conversion device 304 is the photoelectric conversion device 100 described in any of the first to third embodiments and has a function of generating a distance signal indicating a distance to the object 330 based on image light from the object 330 and supplying the generated distance signal to the image processing circuit 306.

The image processing circuit 306 has a function of performing image processing for constructing a distance image based on the distance signal supplied from the photoelectric conversion device 304.

The monitor 308 has a function of displaying a distance image (image data) obtained by image processing in the image processing circuit 306. The memory 310 has a function of storing (recording) a distance image (image data) obtained by image processing in the image processing circuit 306.

As described above, according to the present embodiment, by configuring the range image sensor using the photoelectric conversion devices according to any of the first to third embodiments, it is possible to realize a range image sensor capable of acquiring a range image including more accurate range information in conjunction with improvement in characteristics of the pixels 12.

### Sixth Embodiment

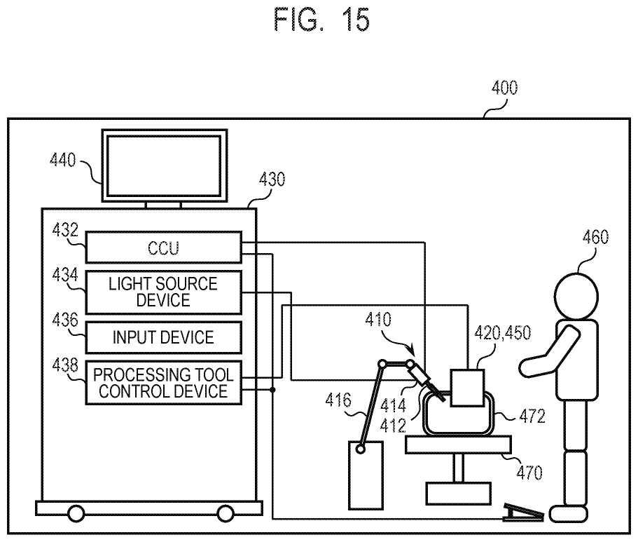

An endoscopic surgical system according to a sixth embodiment of the present invention will be described with reference to FIG. 15. FIG. 15 is a schematic diagram illustrating a configuration example of an endoscopic surgical system according to the present embodiment. In the present embodiment, an endoscopic surgical system will be described as an example of a photodetection system to which the photoelectric conversion device 100 described in any of the first to third embodiments is applied.

FIG. 15 illustrates a state in which an operator (surgeon) 460 performs surgery on a patient 472 on a patient bed 470 using an endoscopic surgical system 400.

As illustrated in FIG. 15, the endoscopic surgical system 400 according to the present embodiment may include an endoscope 410, a surgical tool 420, and a cart 430 on which various devices for endoscopic surgery are mounted. A CCU (Camera Control Unit) 432, a light source device 434, an input device 436, a processing tool control device 438, a display device 440, and the like may be mounted on the cart 430.

The endoscope 410 includes a lens barrel 412 in which an area of a predetermined length from the tip is inserted into a body cavity of the patient 472, and a camera head 414 connected to the base end of the lens barrel 412. Although FIG. 15 illustrates an endoscope 410 configured as a so-called rigid mirror having a rigid lens barrel 412, the endoscope 410 may be configured as a so-called flexible mirror having a flexible lens barrel. The endoscope 410 is held in a movable state by an arm 416.

The tip of the lens barrel 412 is provided with an opening into which the objective lens is fitted. A light source device 434 is connected to the endoscope 410, and light generated by the light source device 434 is guided to the tip of a lens barrel 412 by a light guide extended inside the lens barrel and is irradiated toward an observation target in the body cavity of the patient 472 through the objective lens. Note that the endoscope 410 may be a direct-viewing mirror, an oblique-viewing mirror, or a side-viewing mirror.

An optical system and a photoelectric conversion device (not illustrated) are provided inside the camera head 414 and reflected light (observation light) from the observation target is focused on the photoelectric conversion device by the optical system. The photoelectric conversion device photoelectrically converts the observation light and generates an electrical signal corresponding to the observation light, that is, an image signal corresponding to the observation image. As the photoelectric conversion device, the photoelectric conversion device 100 described in any of the first to third embodiments may be used. The image signal is transmitted to the CCU 432 as RAW data.

The CCU 432 may be configured by a CPU (Central Processing Unit), a GPU (Graphics Processing Unit), or the like, and integrally controls operations of the endoscope 410 and the display device 440. Further, the CCU 432 receives an image signal from the camera head 414 and performs various types of image processing for displaying an image based on the image signal, such as development processing (demosaic processing), on the image signal.

The display device 440 displays an image based on the image signal subjected to the image processing by the CCU 432 under the control of the CCU 432. The light source device 434 may be configured by, for example, a light source such as an LED (Light Emitting Diode) and supplies irradiation light to the endoscope 410 when photographing a surgical part or the like.

The input device 436 is an input interface to the endoscopic surgical system 400. The user may input various kinds of information and input instructions to the endoscopic surgical system 400 via the input device 436.

The processing tool control device 438 controls the driving of the energy processing tool 450 for tissue ablation, incision, blood vessel sealing, or the like.

The light source device 434 that supplies irradiation light to the endoscope 410 when imaging the surgical part may be configured by, for example, a white light source configured by an LED, a laser light source, or a combination thereof. When the white light source is configured by a combination of the RGB laser light sources, since the output intensity and the output timing of each color (each wavelength) may be controlled with high accuracy, the white balance of the captured image may be adjusted in the light source device 434. In addition, in this case, it is also possible to capture an image corresponding to each of RGB in a time division manner by irradiating the observation target with laser light from each of the RGB laser light sources in a time division manner and controlling driving of the imaging element of the camera head 414 in synchronization with the irradiation timing. According to this method, a color image may be obtained without providing a color filter in the image sensor.

Further, the driving of the light source device 434 may be controlled so as to change the intensity of light to be output every predetermined time. By controlling the driving of the image sensor of the camera head 414 in synchronization with the timing of the change of the intensity of the light to acquire an image in a time-division manner and synthesizing the image, it is possible to generate an image having a high dynamic range free from so-called blacked up shadows and blown out highlights.

The light source device 434 may be configured to be capable of supplying light in a predetermined wavelength band corresponding to special light observation. In the special light observation, for example, wavelength dependency of absorption of light in body tissue is utilized. Specifically, a predetermined tissue such as a blood vessel in the superficial layer of a mucous membrane is photographed with high contrast by irradiating light in a narrow band as compared with irradiation light (that is, white light) at the time of normal observation. Alternatively, in the special light observation, fluorescence observation in which an image is obtained by fluorescence generated by irradiation with excitation light may be performed. In the fluorescence observation, a body tissue is irradiated with excitation light to observe fluorescence from the body tissue, or a body tissue is locally injected with a reagent such as indocyanine green (ICG), and the body tissue is irradiated with excitation light corresponding to a fluorescence wavelength of the reagent to obtain a fluorescence image. The light source device 434 may be configured to be capable of supplying narrowband light and/or excitation light corresponding to such special light observation.

As described above, according to the present embodiment, by configuring the endoscopic surgical system using the photoelectric conversion devices according to any of the first to third embodiments, it is possible to realize an endoscopic surgical system capable of acquiring a better quality image.

### Seventh Embodiment

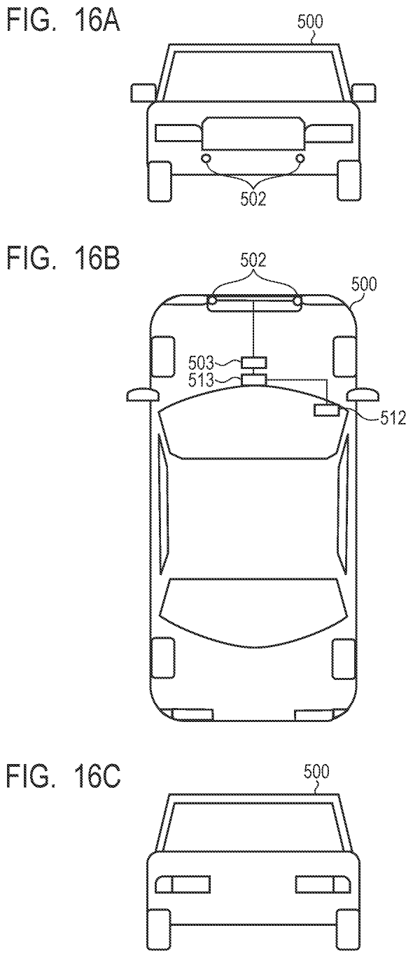

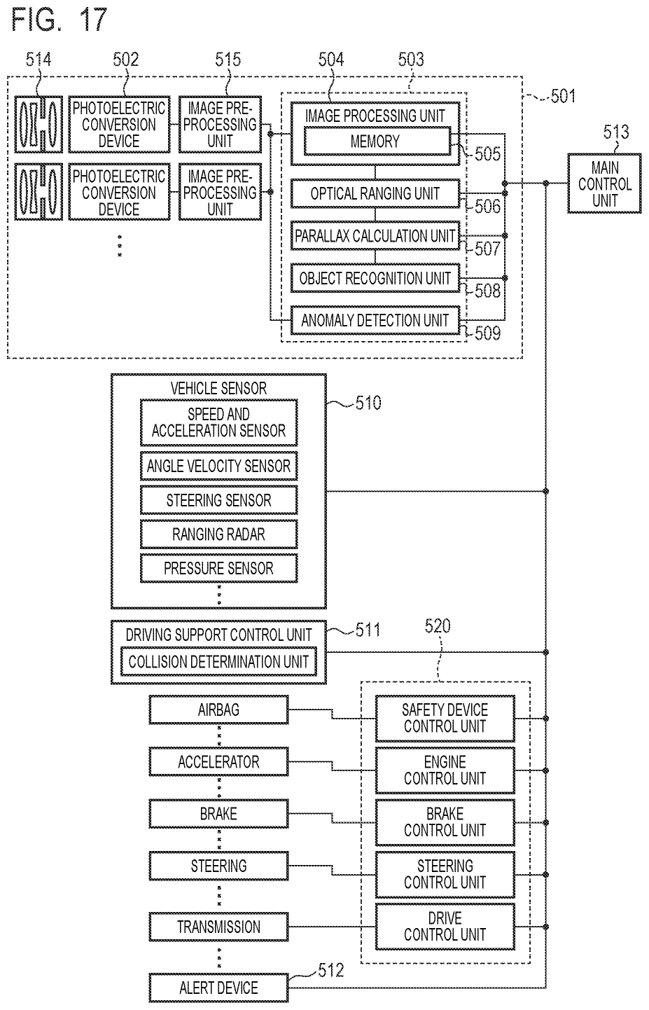

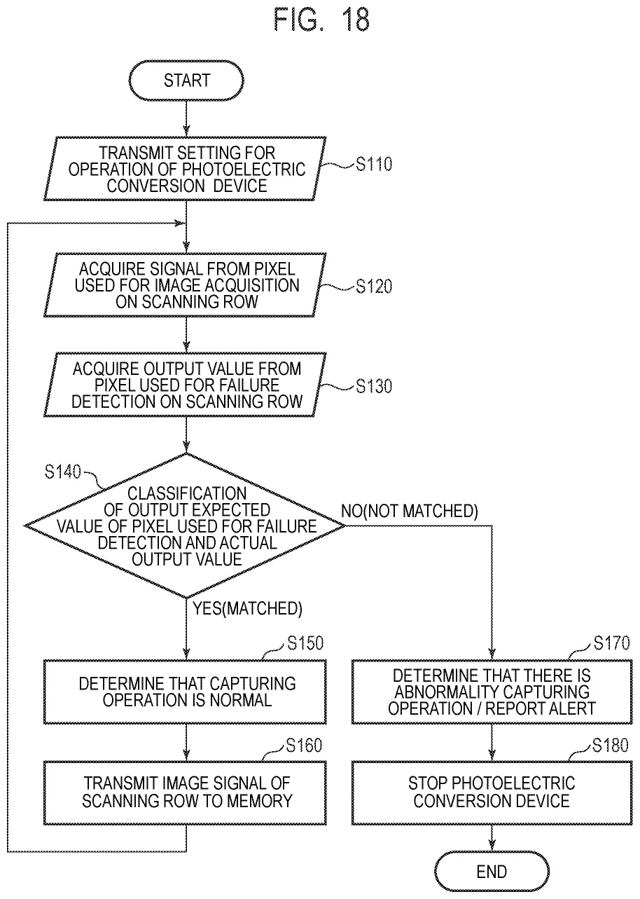

A photodetection system and a movable object according to a seventh embodiment of the present invention will be described with reference to FIG. 16A to FIG. 18. FIG. 16A, FIG. 16B, and FIG. 16C are schematic diagrams illustrating a configuration example of a movable object according to the present embodiment. FIG. 17 is a block diagram illustrating a schematic configuration of a photodetection system according to the present embodiment. FIG. 18 is a flowchart illustrating an operation of the photodetection system according to the present embodiment. In the present embodiment, an application example to an on-vehicle camera will be described as a photodetection system to which the photoelectric conversion device 100 described in any of the first to third embodiments is applied.

FIG. 16A, FIG. 16B, and FIG. 16C are schematic diagrams illustrating a configuration example of a movable object (vehicle system) according to the present embodiment. FIG. 16A, FIG. 16B, and FIG. 16C illustrate a configuration of a vehicle 500 (automobile) as an example of a vehicle system incorporating a photodetection system to which the photoelectric conversion devices described in any of the first to third embodiments are applied. FIG. 16A is a schematic front view of the vehicle 500, FIG. 16B is a schematic plan view of the vehicle 500, and FIG. 16C is a schematic rear view of the vehicle 500. The vehicle 500 includes a pair of photoelectric conversion devices 502 on a front surface thereof. Here, the photoelectric conversion device 502 is the photoelectric conversion device 100 described in any of the first to third embodiments. The vehicle 500 includes an integrated circuit 503, an alert device 512, and a main control unit 513.

FIG. 17 is a block diagram illustrating a configuration example of the photodetection system 501 mounted on the vehicle 500. The photodetection system 501 includes photoelectric conversion devices 502, image preprocessing units 515, an integrated circuit 503, and optical systems 514. The photoelectric conversion device 502 is the photoelectric conversion device 100 described in any of the first to third embodiments. The optical system 514 forms an optical image of an object on the photoelectric conversion device 502. The photoelectric conversion device 502 converts the optical image of the object formed by the optical system 514 into an electrical signal. The image preprocessing unit 515 performs predetermined signal processing on the signal output from the photoelectric conversion device 502. The function of the image preprocessing unit 515 may be incorporated in the photoelectric conversion device 502. At least two sets of the optical system 514, the photoelectric conversion device 502, and the image preprocessing unit 515 are provided in the photodetection system 501, and an output from each set of the image preprocessing unit 515 is input to the integrated circuit 503.

The integrated circuit 503 is an integrated circuit for an imaging system application, and includes an image processing unit 504, an optical ranging unit 506, a parallax calculation unit 507, an object recognition unit 508, and an abnormality detection unit 509. The image processing unit 504 processes the image signal output from the image preprocessing unit 515. For example, the image processing unit 504 performs image processing such as development processing and defect correction on the output signal of the image preprocessing unit 515. The image processing unit 504 includes a memory 505 that temporarily holds the image signal. In the memory 505, for example, the position of a known defective pixel in the photoelectric conversion device 502 may be stored.

The optical ranging unit 506 performs focusing and distance measurement of the object. The parallax calculation unit 507 calculates distance measurement information (distance information) from a plurality of image data (parallax images) acquired by the plurality of photoelectric conversion devices 502. Each of the photoelectric conversion devices 502 may have a configuration capable of acquiring various kinds of information such as distance information. The object recognition unit 508 recognizes the object such as a vehicle, a road, a sign, or a person. Upon detecting an abnormality in the photoelectric conversion device 502, the abnormality detection unit 509 notifies the main control unit 513 of the abnormality.

The integrated circuit 503 may be realized by dedicatedly designed hardware, may be realized by a software module, or may be realized by a combination thereof. Further, it may be realized by FPGA (Field Programmable Gate Array), ASIC (Application Specific Integrated Circuit), or the like, or may be realized by a combination of these.

The main control unit 513 integrally controls the operations of the photodetection system 501, the vehicle sensor 510, the control unit 520, and the like. The vehicle 500 may not include the main control unit 513. In this case, the photoelectric conversion device 502, the vehicle sensor 510, and the control unit 520 transmit and receive control signals via a communication network. For example, the CAN (Controller Area Network) standard may be applied to the transmission and reception of the control signals.

The integrated circuit 503 has a function of receiving a control signal from the main control unit 513 or transmitting a control signal or a setting value to the photoelectric conversion device 502 by its own control unit.

The photodetection system 501 is connected to the vehicle sensor 510 and may detect a traveling state of the host vehicle such as a vehicle speed, a yaw rate, and a steering angle, an environment outside the host vehicle, and states of other vehicles and obstacles. The vehicle sensor 510 is also a distance information acquisition unit that acquires distance information to the object. In addition, the photodetection system 501 is connected to a driving support control unit 511 that performs various kinds of driving support such as automatic steering, automatic traveling, and a collision prevention function. In particular, with respect to the collision determination function, the driving support control unit 511 estimates the collision with other vehicles or obstacles and determines whether or not there is a collision with other vehicles or obstacles based on the detection results of the photodetection system 501 and the vehicle sensor 510. Thus, avoidance control when a collision is estimated and activation of the safety device at the time of the collision are performed.

The photodetection system 501 is also connected to an alert device 512 that issues an alert to the driver based on the determination result of the collision determination unit. For example, when the determination result of the collision determination unit is that the possibility of a collision is high, the main control unit 513 performs vehicle control for avoiding a collision and reducing damage by applying a brake, returning an accelerator, suppressing engine output, or the like. The alert device 512 alerts the user by sounding an alarm such as a sound, displaying alert information on a display screen of a car navigation system, a meter panel, or the like, or vibrating a seat belt or a steering wheel.

In the present embodiment, an image of the surroundings of the vehicle, for example, the front or the rear, is captured by the photodetection system 501. FIG. 16B illustrates an arrangement example of the photodetection system 501 in a case where the photodetection system 501 captures an image in front of the vehicle.

As described above, the photoelectric conversion devices 502 are disposed in front of the vehicle 500. Specifically, it is preferable that a center line with respect to an advancing/retreating direction or an outer shape (for example, a vehicle width) of the vehicle 500 is regarded as a symmetry axis, and two photoelectric conversion devices 502 are disposed line-symmetrically with respect to the symmetry axis in order to acquire distance information between the vehicle 500 and an object to be imaged and determine a possibility of collision. In addition, the photoelectric conversion devices 502 are preferably disposed so as not to interfere with the driver's visual field when the driver visually recognizes a situation outside the vehicle 500 from the driver's seat. The alert device 512 is preferably disposed so as to easily enter the field of view of the driver.

Next, a failure detection operation of the photoelectric conversion device 502 in the photodetection system 501 will be described with reference to FIG. 18. The failure detection operation of the photoelectric conversion device 502 may be performed in accordance with steps S110 to S180 illustrated in FIG. 18.

Step S110 is a step of performing setting at the time of start-up of the photoelectric conversion device 502. That is, the setting for the operation of the photoelectric conversion device 502 is transmitted from the outside of the photodetection system 501 (for example, the main control unit 513) or the inside of the photodetection system 501, and the imaging operation and the failure detection operation of the photoelectric conversion device 502 are started.

Next, in step S120, pixel signals are acquired from the effective pixels. In step S130, an output value from a failure detection pixel provided for failure detection is acquired. The failure detection pixel may include a photoelectric conversion element in the same manner as the effective pixel. A predetermined voltage is written to the photoelectric conversion element of the failure detection pixel. The failure detection pixel outputs a signal corresponding to the voltage written in the photoelectric conversion element. Note that step S120 and step S130 may be reversed.

Next, in step S140, a classification of the output expected value of the failure detection pixel and the actual output value from the failure detection pixel is performed. As a result of the classification in step S140, when the output expected value matches the actual output value, the process proceeds to step S150, it is determined that the imaging operation is normally performed, and the process step proceeds to step S160. In step S160, the pixel signals of the scanning row are transmitted to the memory 505 and temporarily stored. After that, the process returns to step S120 to continue the failure detection operation. On the other hand, as a result of the classification in step S140, when the output expected value does not coincide with the actual output value, the process proceeds to step S170. In step S170, it is determined that there is an abnormality in the imaging operation, and an alert is notified to the main control unit 513 or the alert device 512. The alert device 512 causes the display unit to display that an abnormality has been detected. Thereafter, in step S180, the photoelectric conversion device 502 is stopped, and the operation of the photodetection system 501 is ended.

In the present embodiment, an example in which the flowchart is looped for each row is described, but the flowchart may be looped for each plurality of rows, or the failure detection operation may be performed for each frame. The alert of step S170 may be notified to the outside of the vehicle via a wireless network.

In addition, in the present embodiment, the control in which the own vehicle does not collide with another vehicle has been described, but the present invention is also applicable to control in which the own vehicle follows another vehicle and performs automatic driving, control in which the vehicle performs automatic driving so as not to protrude from a lane, and the like. Further, the photodetection system 501 is not limited to a vehicle such as an own vehicle, and may be applied to, for example, other movable objects (mobile device), such as a ship, an aircraft, an industrial robot, or the like. In addition, the present invention is not limited to the movable object and may be widely applied to equipment using object recognition, such as ITS (Intelligent Transport Systems).

### Eighth Embodiment

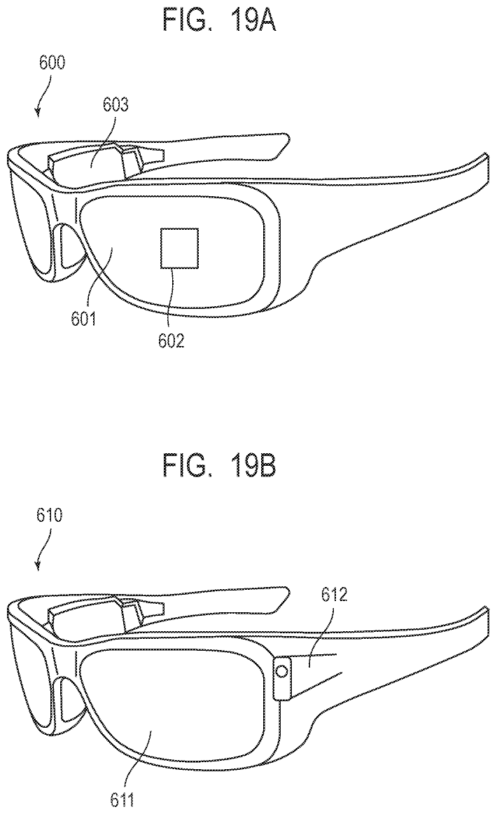

A photodetection system according to an eighth embodiment of the present invention will be described with reference to FIG. 19A and FIG. 19B. FIG. 19A and FIG. 19B are schematic diagrams illustrating a configuration example of the photodetection system according to the present embodiment. In the present embodiment, an application example to eyeglasses (smartglasses) will be described as a photodetection system to which the photoelectric conversion device 100 described in any of the first to third embodiments is applied.

FIG. 19A illustrates eyeglasses 600 (smartglasses) according to one application example. The eyeglasses 600 include lenses 601, a photoelectric conversion device 602, and a control device 603.

The photoelectric conversion device 602 is the photoelectric conversion device 100 described in any of the first to third embodiments and is provided on the lens 601. One photoelectric conversion device 602 may be provided, or a plurality of photoelectric conversion devices may be provided. When a plurality of photoelectric conversion devices 602 are used, a combination of a plurality of types of photoelectric conversion devices 602 may be used. The arrangement position of the photoelectric conversion device 602 is not limited to FIG. 19A. A display device (not illustrated) including a light emitting device such as an OLED (Organic Light Emitting Diode) or an LED (Light Emitting Diode) may be provided on the back surface side of the lens 601.

The control device 603 functions as a power supply that supplies power to the photoelectric conversion device 602 and the display device. The control device 603 has a function of controlling the operations of the photoelectric conversion device 602 and the display device. The lens 601 may be provided with an optical system for focusing light on the photoelectric conversion device 602.

FIG. 19B illustrates eyeglasses 610 (smartglasses) according to another application example. The eyeglasses 610 include lenses 611 and a control device 612. A photoelectric conversion device (not illustrated) corresponding to the photoelectric conversion device 602 and the display device may be mounted on the control device 612.

The lens 611 is provided with a photoelectric conversion device in the control device 612 and an optical system for projecting light from the display device, and an image is projected thereon. The control device 612 functions as a power supply that supplies power to the photoelectric conversion device and the display device and has a function of controlling operations of the photoelectric conversion device and the display device.

The control device 612 may further include a line-of-sight detection unit that detects the line of sight of the wearer. In this case, an infrared light emitting unit may be provided in the control device 612, and infrared light emitted from the infrared light emitting unit may be used for detection of a line of sight. Specifically, the infrared light emitting unit emits infrared light to the eyeball of the user who is watching the display image. A captured image of the eyeball is obtained by detecting reflected light of the emitted infrared light from the eyeball by an imaging unit having a light receiving element. By providing a reduction unit that reduces light from the infrared light emitting unit to the display unit in a plan view, it is possible to reduce degradation of image quality.

The line of sight of the user with respect to the display image may be detected from the captured image of the eyeball obtained by capturing the infrared light. Any known technique can be applied to the line-of-sight detection using the captured image of the eyeball. As an example, a line-of-sight detection method based on a Purkinje image due to reflection of irradiation light on the cornea may be used. More specifically, the line-of-sight detection process based on the pupil corneal reflection method is performed. The line of sight of the user may be detected by calculating a line-of-sight vector representing the orientation (rotation angle) of the eyeball based on the image of the pupil included in the captured image of the eyeball and the Purkinje image using the pupil corneal reflex method.

The display device according to the present embodiment may include a photoelectric conversion device having a light receiving element, and may be configured to control a display image based on line-of-sight information of a user from the photoelectric conversion device. Specifically, the display device determines, based on the line-of-sight information, a first viewing area that the user gazes at and a second viewing area other than the first viewing area. The first viewing area and the second viewing area may be determined by a control device of the display device or may be determined by an external control device. When the determination is made by the external control device, the determination result is transmitted to the display device via communication. In the display area of the display device, the display resolution of the first viewing area may be controlled to be higher than the display resolution of the second viewing area. That is, the resolution of the second viewing area may be lower than the resolution of the first viewing area.

The display area may include a first display area and a second display area different from the first display area, and an area having a high priority may be determined from the first display area and the second display area based on the line-of-sight information. The first display area and the second display area may be determined by a control device of the display device or may be determined by an external control device. When the determination is made by the external control device, the determination result is transmitted to the display device via communication. The resolution of the high priority area may be controlled to be higher than the resolution of the area other than the high priority area. That is, the resolution of the area having a relatively low priority may be lowered.

Note that the AI (Artificial Intelligence) may be used to determine the first viewing area or the area with a high priority. The AI may be a model configured to estimate an angle of the line of sight and a distance to a target object ahead of the line of sight from the image of the eyeball using the image of the eyeball and the direction in which the eyeball of the image is actually viewed as teacher data. The AI program may be included in the display device, the photoelectric conversion device, or the external device. When the external device has the program, the information may be transmitted to the display device via communication.

In the case of performing display control based on visual recognition detection, the present invention may be preferably applied to smartglasses further including a photoelectric conversion device that captures an image of the outside. Smart glasses may display captured external information in real time.

### Modified Embodiments

The present invention is not limited to the above-described embodiments, and various modifications are possible.

For example, an example in which a part of the configuration of any of the embodiments is added to another embodiment or an example in which a part of the configurations of any of the embodiments is substituted with some of the configurations of another embodiment is also an embodiment of the present invention.

Further, the circuit configuration of the pixel 12 is not limited to the above-described embodiment. For example, a switch such as a transistor may be provided between the photoelectric conversion element 22 and the quenching element 24 or between the photoelectric conversion unit 20 and the pixel signal processing unit 30 (waveform shaping unit 32) to control the electrical connection state therebetween. Further, a switch such as a transistor may be provided between the node to which the voltage VH is supplied and the quenching element 24 and/or between the node to which the voltage VL is supplied and the photoelectric conversion element 22 to control an electrical connection state therebetween.

In the above embodiment, the counter circuit 34 is used as the pixel signal processing unit 30, but a TDC (Time to Digital Converter) and a memory may be used instead of the counter circuit 34. In this case, the generation timing of the pulse signal output from the waveform shaping unit 32 is converted into a digital signal by the TDC. A control pulse pREF (reference signal) is supplied to the TDC from the vertical scanning circuit unit 40 via the control line 14 when the timing of the pulse signal is measured. The TDC acquires, as a digital signal, a signal when an input timing of a signal output from each pixel 12 is set to a relative time with reference to the control pulse pREF.

In addition, although a configuration in which one pixel 12 includes one photoelectric conversion element 22 has been described in the above embodiments, one pixel 12 may include a plurality of photoelectric conversion elements 22. Although one photoelectric conversion element 22 is disposed in one well region surrounded by the p-type semiconductor regions 132 and 134 in the above embodiments, a plurality of photoelectric conversion elements 22 may be disposed in one well region.

According to the present invention, it is possible to reduce the drive voltage of the photoelectric conversion element and the photoelectric conversion device. As a result, it is possible to realize energy saving due to low power consumption, to alleviate deterioration in element characteristics due to reduction in heat generation, to reduce dark current, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. Accordingly, the following claims are to be accorded the full scope of the invention.

What is claimed is:

1. A photoelectric conversion element, provided in a semiconductor layer having a first face and a second face opposed to the first face, comprising:
a first semiconductor region of a first conductivity type provided in contact with the first face;
a second semiconductor region of a second conductivity type provided closer to the second face than the first semiconductor region;
a third semiconductor region provided closer to the second face than the second semiconductor region;
a first impurity doped region to which an impurity of the first conductivity type is doped;
a first electrode electrically connected to the first semiconductor region; and
a second electrode electrically connected to the second semiconductor region,
wherein the first semiconductor region and the second semiconductor region constitute an avalanche photodiode, and the avalanche photodiode is configured to multiply a signal charge generated in the third semiconductor region,
wherein a width in a depth direction of a region having an effective impurity density of 1×10¹⁶ cm⁻³ or more of the second semiconductor region is 0.5 μm or less,
wherein the first impurity doped region overlaps the second semiconductor region in a plan view and in the depth direction,
wherein a depth at which a density of a first conductivity type impurity constituting the first impurity doped region has a peak is deeper than a depth at which a density of a second conductivity type impurity constituting the second semiconductor region has a peak,
wherein an impurity density per unit area of the second conductivity type impurity constituting the second semiconductor region is 3×10¹² cm⁻² or more, and
wherein an impurity density per unit area of the first conductivity type impurity constituting the first impurity doped region is not less than 5×10¹¹ cm⁻² and not more than ½ of an impurity density per unit area of the second conductivity type impurity constituting the second semiconductor region.

2. The photoelectric conversion element according to claim 1, wherein a distance from a depth at which an effective impurity density of the first semiconductor region is 1×10¹⁶ cm⁻³ to a depth at which an effective impurity density of the second semiconductor region is 1×10¹⁶ cm⁻³ on a side of the second face with respect to a depth at which the density of the second conductivity type impurity constituting the second semiconductor region has the peak is 0.8 μm or less.

3. The photoelectric conversion element according to claim 1, wherein the first impurity doped region is provided so as to compensate the second conductivity type impurity on a side of the second face with respect to a depth at which the density of the second conductivity type impurity constituting the second semiconductor region has the peak.

4. The photoelectric conversion element according to claim 1, further comprising: a second impurity doped region to which an impurity of the second conductivity type is doped,
wherein the second impurity doped region overlaps the first impurity doped region in the plan view and in the depth direction,
wherein a depth at which a density of the second conductivity type impurity constituting the second impurity doped region has a peak is deeper than a depth at which the density of the first conductivity type impurity constituting the first impurity doped region has the peak, and
wherein an impurity density of the second conductivity type impurity constituting the second impurity doped region is lower than an impurity density of the first conductivity type impurity constituting the first impurity doped region.

5. The photoelectric conversion element according to claim 4, wherein the second impurity doped region is provided so as to compensate the first conductivity type impurity on a side of the second face with respect to a depth at which the density of the first conductivity type impurity constituting the first impurity doped region has the peak.

6. The photoelectric conversion element according to claim 1,
wherein the second semiconductor region includes a first region overlapping the first semiconductor region in the plan view and a second region not overlapping the first region in the plan view, and
wherein an effective impurity density per unit area of a second conductivity type impurity constituting the second semiconductor region is higher in the second region than in the first region.

7. The photoelectric conversion element according to claim 6, wherein the second region is arranged so as to surround the first region.

8. The photoelectric conversion element according to claim 1, further comprising: a fourth semiconductor region of the first conductivity type provided closer to the first face than the second semiconductor region so as to surround the first semiconductor region,
wherein an impurity density of the fourth semiconductor region is lower than an impurity density of the first semiconductor region.

9. The photoelectric conversion element according to claim 1, further comprising:
a fifth semiconductor region of the second conductivity type provided closer to the second face than the third semiconductor region; and
a sixth semiconductor region of the second conductivity type provided so as to surround in the plan view a region in which the first semiconductor region, the second semiconductor region, and the third semiconductor region are arranged, and electrically connected to the second semiconductor region and the fifth semiconductor region.

10. The photoelectric conversion element according to claim 9, wherein the sixth semiconductor region is in contact with the second face.

11. The photoelectric conversion element according to claim 1, wherein the signal charge is a charge carrier of the first conductivity type.

12. A photoelectric conversion device comprising:
a plurality of pixels arranged to form a plurality of rows and a plurality of columns,
wherein each of the plurality of pixels includes the photoelectric conversion element according to claim 1, and a signal processing unit configured to process a signal output from the photoelectric conversion element.

13. The photoelectric conversion device according to claim 12, further comprising:
a first substrate including the semiconductor layer provided with the photoelectric conversion element of each of the plurality of pixels; and
a second substrate provided with the signal processing unit of each of the plurality of pixels.

14. A photodetection system comprising:
a photoelectric conversion device according to claim 12; and
a signal processing device configured to process a signal output from the photoelectric conversion device.

15. The photodetection system according to claim 14, wherein the signal processing device is configured to generate a distance image representing distance information to an object based on the signal.

16. A movable object comprising:
the photoelectric conversion device according to claim 12;
a distance information acquisition unit configured to acquire distance information to an object from a parallax image based on a signal output from the photoelectric conversion device; and
a control unit configured to control the movable object based on the distance information.

17. A method of manufacturing a photoelectric conversion element including a first semiconductor region of a first conductivity type, a second semiconductor region of a second conductivity type, and a third semiconductor region, wherein the first semiconductor region and the second semiconductor region form an avalanche photodiode that multiplies a signal charge generated in the third semiconductor region, the method comprising:
forming the first semiconductor region so as to be in contact with a first face of a semiconductor layer;
forming the second semiconductor region in the semiconductor layer at a depth deeper than a depth at which the first semiconductor region is provided;
forming, by doping an impurity of the first conductivity type in the semiconductor layer, a first impurity doped region so that the first impurity doped region overlaps the second semiconductor region in a depth direction of the semiconductor layer and a depth at which a density of the impurity of the first conductivity type has a peak is arranged deeper than a depth at which a density of an impurity of the second conductivity type constituting the second semiconductor layer has a peak; and
forming, by doping an impurity of the second conductivity type in the semiconductor layer, a second impurity doped region so that the second impurity doped region overlaps the first impurity doped region in the depth direction of the semiconductor layer and a depth at which a density of the impurity of the second conductivity type has a peak is arranged deeper than the depth at which the density of the impurity of the first conductivity type constituting the first impurity doped region has the peak.

18. The method of manufacturing a photoelectric conversion element according to claim 17, wherein a width in the depth direction of the second semiconductor region is controlled by the first impurity doped region.
